(19) United States
(12) Patent Application Publication
(10) Pub. No.: US 2020/0124264 A1
(43) Pub. Date: Apr. 23, 2020

(54) PANEL LIGHT APPARATUS

(71) Applicant: XIAMEN ECO LIGHTING CO. LTD., Xiamen (CN)

(72) Inventors: Guangquan Gong, Xiamen (CN); Jiansheng Zhang, Xiamen (CN); Guanyinlian Liu, Xiamen (CN); Lei Zhang, Xiamen (CN); Haiyan Chen, Xiamen (CN)

(21) Appl. No.: 16/656,181

(22) Filed: Oct. 17, 2019

(30) Foreign Application Priority Data
Oct. 18, 2018 (CN) 201821693885.8

(51) Int. Cl. F21V 29/503; F21V 29/76; H01L 23/367; F21K 9/69; F21K 9/90

(52) U.S. Cl. CPC F21V 29/503; F21V 29/76; F21K 9/90; F21K 9/69; H01L 23/367

(57) ABSTRACT

A panel light apparatus includes a heat sink frame, a first LED light bar, an optical guiding module and a back cover. The first LED light bar has a first plugging structure to be plugged to a second plugging structure of the heat sink frame. Heat of the LED light bar is transmitted to the heat sink frame. The optical guiding module includes a light diffusion layer and a light guiding layer. A lateral side of the light guiding layer faces to LED modules of the first LED light bar for guiding light of the LED modules to the diffusion layer. The light guiding layer and the light diffusion layer are fixed together as an assembly module before being placed in the surrounding border.

### FIELD OF INVENTION

The present invention is related to a panel light apparatus and more particularly related to a panel light apparatus with modular components.

### BACKGROUND

There are various lighting devices designed for satisfying different needs. For example, there are light bulbs to be installed on sockets. Such light bulbs are usually easy to be installed by users. For downlight devices used in normal home, it would be important to consider convenience for installation, safety and replacement.

In addition to consider the user aspect, it is found that manufacturers and sales channels are also important places to provide innovative designs. After all, the total cost of a light device, which affects whether the product may be widely broadcasted, is not only manufacturing and component cost. For example, storage cost in sales channel is also an important factor.

Therefore, it would be beneficial to provide designs that are easily to be installed, assembled, and thus even help decrease total cost. On the other hand, it would be even better if further advantages may be introduced in the same products.

### SUMMARY OF INVENTION

According to an embodiment, a panel light apparatus includes a heat sink frame, a first LED light bar, an optical guiding module and a back cover.

The heat sink frame includes multiple frame bars forming a surrounding border. The first LED light bar is fixed to an inner side of one of the frame bars for fixing the first LED light bar to the heat sink frame. Heat of the LED light bar being transmitted to the heat sink frame.

In some embodiments, the optical guiding module includes a light guiding layer and a light diffusion layer. The LED modules of the first LED light bar emits light into the light guiding layer and then the light is directed to the light diffusion layer to escape.

In some other embodiments, the optical guiding module may further include a reflective layer above the light guiding layer so as to reflect lights escape from the undesired directions back into the light guiding layer and finally to emit into the light diffusion layer.

In some other embodiments, there is further an elastic layer between the back cover and the reflective layer so as to transmit pressure from the back cover to ensure there is no spacing between the reflective layer and the light guiding layer, and no spacing between the light guiding layer and the light diffusion layer. This reduces unnecessary light lost and increase overall luminance efficacy.

The back cover is fixed to the heat sink frame for protecting the optical guiding module.

In some embodiments, the light diffusion layer and the light guiding layer are fixed with a first glue hardened by applying an ultra-violet light.

In some embodiments, furthermore, the reflective layer and the light guiding layer are fixed with a second glue hardened by applying the ultra-violet light. Specifically, three layers of the optical guiding modules are fixed together with glues. The glues are hardened with ultra-violet light and can be applied to the two glues directly or in sequence.

In some embodiments, the second glue between the reflective layer and the light guiding layer may include heat conductive material like metal powder, for enhancing heat dissipation.

In some embodiments, the first glue may contain plastic transparent balls with a diameter less than 0.4 mm. Such plastic transparent balls may further help diffusing light so as to make the light diffusion layer thinner.

In some embodiments, the back cover has a first clip clipping a first side of the reflective layer, the light guiding layer and the light diffusion layer and has a second clip clipping a second side of the reflective layer. The light guiding layer and the light diffusion layer, and the first side is opposite to the second side.

Specifically, two clips are clipping two opposite sides of the multiple layers of the optical guiding module, while leaving other two sides for light to emit into the light guiding layer.

To prevent any layer to escape from the optical guiding module by accident, a stopper structure may be disposed at the third side at a corner of the back cover for preventing the reflective layer, the light guiding layer or the light diffusion layer to escape from the third side.

In some embodiments, the back cover has a convex portion pressing the reflective layer to keep the reflective layer leaving no space with the light guiding layer. This design may save the need of inserting an elastic layer.

Otherwise, In some embodiments, there may be an elastic layer on the reflective layer. In addition, a third glue may be applied between the elastic layer and the reflective layer.

Similarly, the third glue is hardened together with the first glue and the second glue in the same procedure.

In addition, the third glue has heat dissipation characteristics, e.g. containing metal powder, so that heat may be transmitted to the back cover to increase life span of the components of the panel light apparatus.

According to an embodiment, a panel light apparatus includes a heat sink frame, a first LED light bar, an optical guiding module, an elongated side cover, a back cover and a driver box. The panel light apparatus may be installed below a ceiling, attach to a wall or installed in other applications. The heat sink frame defines light output shape, e.g. a rectangular light output shape. The thickness of the panel light apparatus is usually smaller than width of the light output shape. Usually, the thickness of the panel light apparatus is smaller than normal downlight devices so that the panel light apparatus does not need an additional installation cavity, e.g. in a ceiling.

The heat sink frame includes a plurality of frame bars forming a surrounding border. For example, if the heat sink frame has a rectangular shape, there are four frame bars at four sides. The four frame bars form a rectangular surrounding border. Please be noted that the frame bar may also be made of one or multiple frame bars to form different shapes, e.g. circular, ellipse or other shapes.

The first LED light bar is disposed on an inner side of one of the frame bars for fixing the first LED light bar to the heat sink frame. Heat of the LED light bar is transmitted to the heat sink frame. The first LED light bar includes multiple first LED modules disposed along an elongated axis. A maximum spacing between adjust two first LED modules being a first width. For example, a rectangular panel light has four elongated frame bars. The first LED light bar has a similar shape as the frame bar to attach to. The first LED light bar has an elongated axis in parallel with the lateral side wall of the associated frame bar.

Besides, the first LED light bar is a major heat source, and heat generated from the first LED light bar is transmitted to the frame bars of the heat sink frame.

The optical guiding module is placed in the surrounding border. For example, the surrounding border is a rectangular shape and the optical guiding module is also a similar rectangular shape but with a smaller size. The optical guiding module is placed in the enclosing border of the heat sink frame.

The optical guiding module may have a light diffusion layer and a light guiding layer. The light guiding layer may be a transparent plastic board a plurality of micro structures for guiding light received from a lateral side of the transparent plastic board to route in the light guiding layer and then escapes the light guiding layer from a plurality of micro optical structures, e.g. micro cavities, that may be formed on the transparent plastic board using laser beams or molding technologies.

The light guiding layer has a lateral side facing to LED modules of the first LED light bar for guiding light of the LED modules to the diffusion layer via the light guiding layer and then to escape from a front side of the optical guiding module.

In addition, the light guiding layer and the light diffusion layer are fixed together as an assembly module before being placed in the surrounding border. With such design, it is easy to assembly the final product by placing all components together. For example, when the light guiding layer and the light diffusion layer are fixed together as an assembly module, a manufacturer, even a distributor or a customer, may easily place these components together, instead of needing to positioning, aligning these components.

The back cover is fixed to the heat sink frame for protecting the optical guiding module. The driver box converts an external power to a driving current for the first LED modules.

In addition, the panel light apparatus also has a multi-type connector structure for selectively connecting to one of multiple types of fixing devices. The fixing devices are corresponding to different types of stations for fixing the panel light apparatus to one selected station.

Specifically, for different types of stations that provide different connection methods, different fixing devices need to be used. With the multi-type connector structure, users or manufacturers first determine what type of station they need to face, and choose accordingly a corresponding fixing device to connect on the multi-type connector structure. When the chosen fixing device is installed to the multi-type connector structure, the panel light apparatus may be properly fixed to the station as needed.

Such configuration makes it more convenient and more flexible to prepare components and save storage cost.

In some embodiments, the multi-type connector structure includes multiple screw holes. A portion of these screw holes are shared by different fixing devices.

For example, in some embodiments, the panel light apparatus is directory fixed to a station, e.g. a ceiling structure, by fastening screws into corresponding screw holes.

In some other embodiments, a portion of the screw holes are used for connecting to spring clips. Such spring clip has a first part with a first end connected to the screw holes and with a second end connected to a second part with a spring. The second part is elastically expandable with respect to the first part for inserting into a cavity of one of the stations and then expanded to fix to a station.

Specifically, the overall size of the first part and the second part of the spring clip may be squeezed to decrease to enter an entrance of an installation hole. After the spring clip enters the entrance hole, the second part recovers its respective distance to the first part of the spring clip, i.e. to expand, and thus to prevent the panel light apparatus to escape from the entrance hole.

In some examples, such spring clips may be installed on two opposite sides of the heat sink frame. More than two spring clips may also be used for larger panel light apparatus.

In some embodiments, a portion of screw holes are used for connecting to vertical bars. The vertical bars have protruding parts in lateral sides of the vertical bars. Such fixing devices are used for stations that have one or more elastic clip receivers. The elastic clip receiver has a concave space for containing the protruding part of the vertical bar for fixing the panel light apparatus to said one station.

Specifically, the elastic clip of such station has an entrance slit for receiving the vertical bar. When the protruding part enters the concave space of the elastic clip, the elastic force keeps the protruding part of the vertical bar in the concave space and thus fixes the panel light apparatus to the station.

Some screw holes on the panel light apparatuses may be shared by multiple fixing devices. For example, the vertical bar and the spring clip may share one screw hole while using additional different screws.

In some embodiments, the fixing device is fixed to the multi-type connector structure with a one-way connection unit. For example, the one-way connection unit may have an inverse hook so that it is easier to attach the fixing device to the multi-type connector structure than detach the fixing device away from the multi-type connector structure.

In other words, in addition to using screw holes, other devices may be used for installing the fixing devices.

In some embodiment, the fixing device has an embedded connector for routing electricity to the first LED modules. In some embodiments, the heat sink may have embedded connectors, e.g. hidden and plugged in the frame bar of the heat sink frame. In such case, the fixing devices may also fix to the heat sink frame and may be embedded with wires or other connectors for transmitting electricity or control signals from or to the driver box or other devices.

In some embodiments, the driver box is fixed to the back cover and placed away from peripheral part of the back cover. For example, the driver box is fixed at middle of the back cover.

In some embodiments, the multi-type connector structure is placed on a different frame bar other than the frame bar disposing the first LED light bar. For example, there are LED light bars installed on two opposite sides of a panel light apparatus. The other two unused sides of the heat sink frame may be used for disposing the multi-type connector structures, so as to perform wire connection or prevent damage of components.

In some other embodiments, the multi-type connector structure is placed on the same frame bar disposing the first LED light bar. With such design, the multi-type connector device, which further connected to a fixing device, may help perform heat dissipation, particularly heat generated from the LED light bar.

In some embodiments, the multi-type connector structure and the fixing device is also attracted by magnetic force. By using magnetic components, it is easier to assemble the multi-type connector structure to corresponding fixing devices. This is particularly helpful when the design is to be used by distribution sellers that assemble the panel light apparatuses.

In some embodiments, the multi-type connector structure is fixed on a fixing bar. The fixing bar is used for fixing the back cover and the first LED light bar to the heat sink frame. Specifically, the multi-type connector structure is fixed indirectly to the heat sink frame, via an intermediate unit, the fixing bar. In following drawings and examples, fixing bars may be used for fixing the LED light bar and the optical guiding module to the heat sink frame. In this embodiment, the multi-type connector structure is fixed on the fixing bar first. Such design makes post-assembling easier, particularly when there are more than one fixing device to be installed on one side of the heat sink frame.

In other embodiments, the multi-type connector structure is fixing to a sliding bar to be inserted into a corresponding track of the heat sink frame. In other words, the sliding bar replaces the fixing bar explained in previous paragraph. A corresponding track of the heat sink frame may be designed so that the sliding bar with fixing devices may be directly to the heat sink frame.

In some embodiments, the multi-type connector structure is fixed to a fixing frame, and the fixing frame is fixed to the heat sink frame. In such design, particularly when there are multiple multi-type connector structures. These multi-type connector structures, sometimes further including fixing devices thereon, are fixed to the fixing frame. Then, the fixing frame is attached to the heat sink frame, e.g. by clipping or screws.

In some embodiments, the driver has a slot for connecting to an external emergency battery. For example, the driver box may have a USB socket to connect to a common USB battery box. Furthermore, the multi-type connector structure may also be able to connect to a temporary stand so as to keep the panel light apparatus at a predetermined pose when necessary. For example, when the USB battery box is plugged, the panel light apparatus may be removed from the ceiling and placed on a table. At such time, the temporary stand and the USB battery box makes the panel light apparatus a temporary light apparatus for emergency use.

In some embodiments, the multi-type connector structure is used for fix to another panel light apparatus as a module. For example, multiple panel light apparatuses may be combined as a cluster. The multi-type connector structures may be used for fixing to other panel light apparatuses. Furthermore, the multi-type connector structures may also help for transmitting electricity and even control signals.

According to an embodiment, a panel light apparatus includes a heat sink frame, a first LED light bar, an optical guiding module, an elongated side cover and a back cover. The panel light apparatus may be installed below a ceiling, attach to a wall or installed in other applications. The heat sink frame defines light output shape, e.g. a rectangular light output shape. The thickness of the panel light apparatus is usually smaller than width of the light output shape. Usually, the thickness of the panel light apparatus is smaller than normal downlight devices so that the panel light apparatus does not need an additional installation cavity, e.g. in a ceiling.

The heat sink frame includes a plurality of frame bars forming a surrounding border. For example, if the heat sink frame has a rectangular shape, there are four frame bars at four sides. The four frame bars form a rectangular surrounding border. Please be noted that the frame bar may also be made of one or multiple frame bars to form different shapes, e.g. circular, ellipse or other shapes.

The first LED light bar is disposed on an inner side of one of the frame bars for fixing the first LED light bar to the heat sink frame. Heat of the LED light bar is transmitted to the heat sink frame. The first LED light bar includes multiple first LED modules disposed along an elongated axis. A maximum spacing between adjust two first LED modules being a first width. For example, a rectangular panel light has four elongated frame bars. The first LED light bar has a similar shape as the frame bar to attach to. The first LED light bar has an elongated axis in parallel with the lateral side wall of the associated frame bar.

Besides, the first LED light bar is a major heat source, and heat generated from the first LED light bar is transmitted to the frame bars of the heat sink frame.

The optical guiding module is placed in the surrounding border. For example, the surrounding border is a rectangular shape and the optical guiding module is also a similar rectangular shape but with a smaller size. The optical guiding module is placed in the enclosing border of the heat sink frame.

The optical guiding module may have a light diffusion layer and a light guiding layer. The light guiding layer may be a transparent plastic board a plurality of micro structures for guiding light received from a lateral side of the transparent plastic board to route in the light guiding layer and then escapes the light guiding layer from a plurality of micro optical structures, e.g. micro cavities, that may be formed on the transparent plastic board using laser beams or molding technologies.

The light guiding layer has a lateral side facing to LED modules of the first LED light bar for guiding light of the LED modules to the diffusion layer via the light guiding layer and then to escape from a front side of the optical guiding module.

The light diffusion layer is used for diffusing light so that the light would not look too hash for human eyes, e.g. to soften the output light and to avoid users see a series of strong light points.

In addition, the light guiding layer and the light diffusion layer are fixed together as an assembly module before being placed in the surrounding border. With such design, it is easy to assembly the final product by placing all components together. For example, when the light guiding layer and the light diffusion layer are fixed together as an assembly module, a manufacturer, even a distributor or a customer, may easily place these components together, instead of needing to positioning, aligning these components.

The back cover is fixed to the heat sink frame for protecting the optical guiding module.

In addition, a supplemental electronic device is attached to a bottom side of the heat sink frame. There are several useful supplemental electronic devices that may be attached to the bottom side of the heat sink frame. For example, an indicator for indicating an emergency working status, an indicator for indicating a wireless operation mode or connection status, a detector for detecting environment luminance level to determine whether to turn on, to turn off, or to adjust a luminance level of the panel light apparatus.

More details and examples are provided as follows for more clearly explaining these embodiments.

In some embodiments, the supplemental electronic device is an indicator for showing an emergency device status. The supplemental electronic device is attached to the bottom surface of the heat sink frame with a tape. To prevent sudden electricity interrupt, people sometimes requires their light devices having the capacity of handling electricity interrupt, which is one of emergency situations. In such embodiments, an emergency battery is usually prepared. When an electricity interrupt occurs, a detector finds the situation and automatically routes power supply of the first LED modules from normal indoor power supply to the emergency battery.

However, it is important to notify users whether the emergency batter is still ok. Therefore, a low power is directed to an indicator, e.g. an LED indicator, to show the status of the emergency battery, which is part of an emergency device.

The indicator, in this case, is the supplemental electronic device. A tape may be used for attaching the indicator to the bottom surface of the panel light apparatus.

In some embodiments, the driver box has a slot for plugging in an emergency module for providing emergency power to the first LED modules when the external power source is interrupted. Specifically, the driver box may have a container for directly containing an emergency battery and corresponding circuit. Alternatively, the slot is for plugging a terminal of the emergency device, the terminal is further connected to the emergency battery.

In some embodiments, the bottom surface has a plug-in socket for plugging in an indicator as the supplemental electronic device. In such embodiments, the indicator or other supplemental electronic device is not directly fixed to the bottom surface of the heat sink frame. Instead, a plug-in socket may be provided. There may be different types of supplemental electronic devices to be integrated with the same panel light apparatus, depending on customer needs. In some case, the plug-in socket may even be kept empty without plugging any device, if needed.

The plug-in socket is further connected to the first LED modules or other components of the panel light apparatus, e.g. an emergency battery control circuit via certain embedded connectors pre-installed inside the heat sink frame.

Such embedded connectors may be wires, conductive clips or other electricity connectors. The embedded connectors may be even designed as a plugging style. Specifically, no welding is needed for assembling the embedded connectors to the heat sink frame. Furthermore, it is convenient for users to adjust or replace a different kind of embedded connector to the same panel light apparatus depending on different needs or product requirements, e.g. different pricing.

As mentioned above, there may be various kinds of supplemental electronic device. For example, the supplemental electronic device may be an indicator for showing a status of an emergency device. For another example, the supplemental electronic device may be a light detector for detecting an environment luminance level, the driver box determines turning on the first LED modules automatically according to the detected environment luminance level. For example, when there is a window in a room and sunshine comes into the room in day time. The luminance level is sufficient and detected. The first LED modules may be turn on with a lower luminance level. Alternatively, the first LED modules may also have only turn-on and turn-off modes, depending on product requirements.

In some other embodiments, the supplemental electronic device may be a motion sensor for detecting whether there is a person moving around the panel light apparatus. For example, even in night time when the panel light apparatus is turned off, the panel light apparatus may be turned on automatically when detecting some person moving around the panel light apparatus. The bottom surface of the heat sink frame is a great place for placing such sensors or detectors. Such detectors may contain an IR (Infrared) sensor, or a radar sensor with associated circuits. Part of the components may be placed in the driver box. The wiring for transmitting electricity and signals may be routed via the heat sink frame.

In some embodiments, one supplemental electronic device of one panel light apparatus may be shared by multiple panel light apparatuses. In other words, when multiple panel light apparatuses are installed as a cluster, e.g. at the same room, only one or some panel light apparatuses need to be added such supplemental electronic devices. Alternatively, every panel light apparatus is disposed its own supplemental electronic device, like indicators, light sensors, motion sensors, but information of these supplemental electronic devices are shared among these panel light apparatuses.

The information may be shared via a wire or a wireless channel. For example, when a cluster of panel light apparatuses are installed to a ceiling, users may use wires to plug in pre-installed socket to connect these panel light apparatuses together as a cluster. When these panel light apparatuses are connected, information or control commands may be received or sent to the supplemental electronic device.

With such design, manufacturing cost may be reduced when some panel light apparatuses may share the supplemental electronic device of other panel light apparatus, instead of installing one such supplemental electronic device on the panel light apparatus. Alternatively, even every panel light apparatus is disposed one supplemental electronic device, collected information or control commands of the supplemental electronic devices may be shared among these panel light apparatuses.

For example, a day light sensor of a panel light apparatus that is installed close to a window may be designated as the major reference for determining whether a cluster of panel light apparatuses need to be turned on or to turn off. This saves more accuracy and sometimes decreases control complexity.

In some embodiments, multiple panel apparatuses may share the same set of control circuits in a driver box of one panel light apparatus. In such design, multiple panel light apparatuses may be controlled together with one shared control circuit. This may save manufacturing cost and/or decrease control complexity.

In some embodiments, multiple panel apparatuses may even share the same driver box. In such design, even driving current is supplied from a driver box to multiple panel light apparatuses. This is particularly helpful when in most office or home, multiple panel light apparatuses are installed close to each other to provide sufficient luminance level or to cover more areas. When a driver box may be shared among multiple panel light apparatuses, the installation is simplified and the cost of the product is also reduced.

In some embodiments, multiple panel light apparatuses may be connected in series, in addition to sharing one driver box for these panel light apparatuses.

In some embodiments, the driver box controls the first LED modules to provide an operation status of an emergence device. Instead of using a specific indicator for showing whether an emergency battery and associated circuits are normal, certain testing procedure and light patterns may be provided to tell users whether the emergency battery and associated circuits are working normally. For example, every time when the panel light apparatus is turned on, the first LED modules are turned on and turned off for three times in three seconds, if the emergency battery is ok. A blinking light pattern may be used for indicating users that there is certain problem in the emergency battery.

In some embodiments, the driver box may be disposed with a driver circuit. The driver circuit may detect dynamically the status of the emergency battery. Most batteries may have a shorter life span if they are not used, not charged, or not discharged for a long time. The driver circuit may be coded to execute a charging, discharging schedule for increasing the life span of the emergency battery.

In some embodiments, the supplemental electronic device disposed on the bottom side of the heat sink frame may be used for connecting to an external battery device, like common USB battery boxes people usually carry for charging their mobile phones. In such case, the supplemental electronic device may be an USB socket for connecting to a USB battery box as emergency use.

In earthquakes, typhoon, or hospital situations, such function may be particularly important and helpful. Since many people today carry USB battery boxes with them, it is not difficult to use such USB battery box as an emergency purpose, particularly when the pre-installed emergency battery in the panel light apparatus is running out of electricity or out of order.

In some embodiments, there may be a holding structure, like a hook, a containing box, a clip or other structures for holding the USB battery box mentioned above. For example, when there is a sudden electricity interrupt, users may just connect their portable USB battery box to the panel light. It is quite different to provide light from a ceiling and from a table when accident happens. When one USB battery box is running out of electricity, another USB battery box may be replaced immediately, which sometimes may even save human life.

In some embodiments, the heat sink frame may further have a temporary stand so that the panel light apparatus is located at a predetermined position to work normally. In certain extreme cases, the panel light apparatuses may even be used as a temporary light source. If there is a revocable stand that helps the panel light apparatus to stand as a pose for emitting light to a desired direction, this makes the panel light apparatus even more helpful.

In some embodiments, the driver box switches from a normal mode to an emergency working mode when an emergency battery is started to supply electricity to the first LED modules. The current supplied to the first LED modules is different between the emergency mode and the normal mode. For example, in emergency working mode, the luminance level of the first LED modules may be adjusted to a lower level.

In some embodiments, particularly when the driver box has a wireless circuit for receiving more complicated commands, an estimated time period for electricity interrupt may be provided to the driver box. The driver box calculates current battery volume and related history statistics and designs an electricity scheme, trying to keep the panel light apparatus to keep providing light during the estimated time period.

In some embodiments, a wire has a first end connecting to the driver box and has a second end connecting to an indicator, the indicator is attached to the bottom surface of the heat sink frame with a tape.

In some other embodiments, a wire has a first end connecting to the driver box and has a second end connecting to an indicator, the indicator is attached to the bottom surface of the heat sink frame with a magnet unit.

According to an embodiment, a panel light apparatus includes a heat sink frame, a first LED light bar, an optical guiding module, an elongated side cover and a back cover. The panel light apparatus may be installed below a ceiling, attach to a wall or installed in other applications. The heat sink frame defines light output shape, e.g. a rectangular light output shape. The thickness of the panel light apparatus is usually smaller than width of the light output shape. Usually, the thickness of the panel light apparatus is smaller than normal downlight devices so that the panel light apparatus does not need an additional installation cavity, e.g. in a ceiling.

The heat sink frame includes a plurality of frame bars forming a surrounding border. For example, if the heat sink frame has a rectangular shape, there are four frame bars at four sides. The four frame bars form a rectangular surrounding border. Please be noted that the frame bar may also be made of one or multiple frame bars to form different shapes, e.g. circular, ellipse, two connected rectangular shapes like a digit ‘8’ or other shapes.

The first LED light bar is disposed on an inner side of one of the frame bars for fixing the first LED light bar to the heat sink frame. Heat of the LED light bar is transmitted to the heat sink frame. The first LED light bar includes multiple first LED modules disposed along an elongated axis. A maximum spacing between adjust two first LED modules being a first width. For example, a rectangular panel light has four elongated frame bars. The first LED light bar has a similar shape as the frame bar to attach to. The first LED light bar has an elongated axis in parallel with the lateral side wall of the associated frame bar. For example, 101 LED modules are placed with 5 mm distance to each other within a length of a 50 cm LED light bar. The 5 mm distance is the first width. There may be some distance larger than others. In such case, the maximum value is taken as the first width.

Besides, the first LED light bar is a major heat source, and heat generated from the first LED light bar is transmitted to the frame bars of the heat sink frame.

The optical guiding module is placed in the surrounding border. For example, the surrounding border is a rectangular shape and the optical guiding module is also a similar rectangular shape but with a smaller size. The optical guiding module is placed in the enclosing border of the heat sink frame.

The optical guiding module may have a light diffusion layer and a light guiding layer. The light guiding layer may be a transparent plastic board a plurality of micro structures for guiding light received from a lateral side of the transparent plastic board to route in the light guiding layer and then escapes the light guiding layer from a plurality of micro optical structures, e.g. micro cavities, that may be formed on the transparent plastic board using laser beams or molding technologies.

The light guiding layer has a lateral side facing to LED modules of the first LED light bar for guiding light of the LED modules to the diffusion layer via the light guiding layer and then to escape from a front side of the optical guiding module.

The light diffusion layer is used for diffusing light so that the light would not look too hash for human eyes, e.g. to soften the output light and to avoid users see a series of strong light points.

In addition, the light guiding layer and the light diffusion layer are fixed together as an assembly module before being placed in the surrounding border. With such design, it is easy to assembly the final product by placing all components together. For example, when the light guiding layer and the light diffusion layer are fixed together as an assembly module, a manufacturer, even a distributor or a customer, may easily place these components together, instead of needing to positioning, aligning these components.

The elongated side cover is connected to the frame bar carrying the first LED light bar. The elongated side cover has a top surface facing to the light diffusion layer. A width of the elongated side cover is referred as the second width. The ratio between the first width to the second width is smaller than 1.5. That is, the result of taking the first width dividing with the second width is kept less than 1.5.

With such design, bright points problem may be solved or softened, making the overall light output more perfect.

The back cover is fixed to the heat sink frame for protecting the optical guiding module.

In some embodiments, a reflective layer is disposed between the top surface of the elongated side cover and the light diffusion layer. Light emitting on the reflective layer above the elongated side cover is reflected back to the optical guiding module, and then after certain routing, the light finally moves out of the optical guiding module. This saves unnecessary light waste and prevent undesired heat generation.

In some embodiments, the reflective layer is a heat conductive layer for transmitting heat to the heat sink frame. In other words, the reflective layer, in addition to reduce light waste, the reflective layer above the elongated side cover may be made of metal or heat conductive plastic material for enhance overall heat dissipation of the panel light apparatus.

In some embodiments, there may also be second LED modules. A maximum spacing between adjust two second LED modules is a third width. The ratio between the third width to the second width is smaller than 1.5.

In some embodiments, the second LED modules and the first LED modules are arranged alternatingly to each other. Specifically, along the elongated axis as mentioned above, one first LED module is placed first, then one second LED module is placed, then another first LED module is placed, and then another second LED module is placed. With such order, the first LED modules and the second LED modules may be arranged alternating to each other.

In some other embodiments, the first LED modules and the second LED modules are arranged as two rows in parallel. In such embodiments, the first LED modules may form a line in parallel with the elongated axis as mentioned above. The second LED modules form another line also in parallel with the elongated axis as mentioned above. In such design, the two LED modules form two rows in parallel.

In some embodiments, the second LED modules are mounted on a second LED light bar on another frame bar opposite to the frame bar mounted with the first LED modules. Specifically, there are two LED light bars fixed on two opposite frame bars in a panel light apparatus. The first LED light bar is fixed with first LED modules and the second bar is fixed with second LED modules. The first LED modules and the second LED modules may have different color temperatures.

In some embodiments, the first LED modules are connected in series and the second LED modules are connected in series. The first LED modules and the second LED modules have different color temperatures. The second LED modules are connected in series to a resistor before connecting to the first LED modules. With such configuration, when the total working current is increasing, the overall mixed color temperature may be adjusted in addition to its overall luminance level. With the resistor, the first LED modules and the second LED modules receive different current increasing speed and thus changes the mixed color temperature during changing its mixed brightness.

Such feature is capable of simulating day light from sunrise to full bright sunshine. This is an attractive feature, particularly for light devices that provide color temperature adjustment.

In some embodiments, the elongated side cover has more apparent light diffusion effect than the light diffusion layer. Specifically, the elongated side cover may completely prevent any light to go through. In some other cases, the elongated side cover may be designed with light diffusion effect. Particularly, to prevent certain bright points to be seen, the elongated side cover may have stronger light diffusion effect than the light diffusion layer in the optical guiding module. In other words, bright points may be shielded or soften by the elongated side cover. More light is output while certain light effect is kept.

In some embodiments, the first LED light bar comprises multiple LED packages. Each LED package comprises LED modules of different color temperatures. For example, the first LED modules and the second LED modules are separately assembled together into multiple LED packages. In other words, each LED package may have one first LED module and one second LED module. To achieve different design needs, four lines, instead of two lines, may be provided for such LED modules. In such case, the color temperature may be adjusted while the LED packages may be placed close enough to prevent undesired light effect like bright points.

In some embodiments, a lens bar may be disposed facing to the first LED modules for diffusing light of the first LED modules before the light entering the light guiding layer. Specifically, such lens bar containing multiple lens corresponding to each LED module may be placed between the LED modules and the light guiding layer. With such design, light is diffused first and bright points may be eliminated or softened.

In some embodiments, a reflector layer may be disposed behind first LED modules. The reflective layer has concave texture for generating diffused reflecting light into the light guiding layer. Specifically, some light is emitted directly to the light guiding layer while some other light may be escape to the back side of the first LED modules, e.g. the surface of the first LED light bar. The reflective layer mentioned here may collect such light and reflect the light back into the light guiding layer. Furthermore, the reflective layer may be disposed with multiple concave structures, just like diffusion lens, for randomizing its reflected light. This may also help remove or soften the bright point problem.

In some embodiments, a diffusion layer between the first LED modules and the light guiding layer. In other words, light emitted to the light guiding layer is passing the second diffusing layer between the first LED modules and the light guiding layer. This may also help remove or soften the bright point problem.

In some embodiments, the first LED light bar is integrated with the elongated side cover as an assembling component. Since the parameter, like its width, of the elongated side cover is related to spacing between two adjacent LED modules on the LED light bar. It would be beneficial to integrate the LED light bar with the elongated side cover. In such design, manufactures may manufacture modules of LED light bars and elongated side covers with several different parameters and choose desired modules to be assembled in final product. In such design, the heat sink frame and other components may not need to be changed. Only the LED light bars and associated elongated side covers need to be selected or replaced.

In some embodiments, the first LED light bar has a plugging structure to be plugged into the frame bar of the heat sink frame. With such design, it would be much easier to assemble the first LED light bar to other components of the panel light apparatus. For example, no complicated welding is necessary when the plugging structure is strong enough to fix the first LED light bar to other components.

In some embodiments, the first LED light bar has a terminal to be plugged into the heat sink frame for receiving electricity. In addition to the plugging structures as mentioned above, the LED light bar may be disposed with a terminal so as to receive electricity and/or control signal from the heat sink frame.

Certain embedded connectors, e.g. metal strips or metal wires with corresponding insulation parts, may be disposed in the heat sink frame. Such embedded connectors may be even pluggable, e.g. no welding but only plugging in a corresponding plug-in structure.

In some embodiments, the elongated side cover is a plug-in component to be plugged to the heat sink frame. In some cases, the elongated side cover may be part of the frame bar. In some other cases, the elongated side cover may be an additional component to be plugged, or connected in other ways, to the heat frame sink.

In some embodiments, the panel light apparatus may include a driver box. The driver box has a slot for plugging an external plug-in module. There may be multiple types of the external plug-in modules to be plugged into the slot for extending the function of the driver box. In some application, an external plug-in module may provide color temperature adjustment of the panel light apparatus.

In some embodiments, the driver box is connected to socket of the heat sink frame and transmits a driving current to the first LED modules via an embedded connector in the heat sink frame.

According to an embodiment, a panel light apparatus includes a heat sink frame, a first LED light bar, an optical guiding module and a back cover. The panel light apparatus may be installed below a ceiling, attach to a wall or installed in other applications. The heat sink frame defines light output shape, e.g. a rectangular light output shape. The thickness of the panel light apparatus is usually smaller than width of the light output shape. Usually, the thickness of the panel light apparatus is smaller than normal downlight devices so that the panel light apparatus does not need an additional installation cavity, e.g. in a ceiling.

The heat sink frame includes a plurality of frame bars forming a surrounding border. For example, if the heat sink frame has a rectangular shape, there are four frame bars at four sides. The four frame bars form a rectangular surrounding border. Please be noted that the frame bar may also be made of one or multiple frame bars to form different shapes, e.g. circular, ellipse, two connected rectangular shapes like a digit ‘8’ or other shapes.

The first LED light bar has a first plugging structure to be plugged to a second plugging structure on an inner side of one of the frame bars. For example, if the panel light apparatus is a rectangular shape panel light, there are four frame bars as mentioned above. One frame bar is disposed with a second plugging structure associating with a first plugging structure of a LED light bar. The first plugging structure may be a male pin when the second plugging structure may be a female socket, and vice versa. The first plugging structure and the second plugging structure may provide both structural connection and electricity connection. In other words, the first LED bar may receive electricity from the connection of the first plugging structure and the second plugging structure. Meanwhile, the first LED bar is fixed to the heat sink frame by the connection of the first plugging structure and the second plugging structure. Please be noted that the plugging structure may have various shapes, e.g. elastic clips, hooks and associates connecting structures.

Besides, the first LED light bar is a major heat source, and heat generated from the first LED light bar is transmitted to the frame bars of the heat sink frame.

The optical guiding module is placed in the surrounding border. For example, the surrounding border is a rectangular shape and the optical guiding module is also a similar rectangular shape but with a smaller size. The optical guiding module is placed in the enclosing border of the heat sink frame.

The optical guiding module may have a light diffusion layer and a light guiding layer. The light guiding layer may be a transparent plastic board a plurality of micro structures for guiding light received from a lateral side of the transparent plastic board to route in the light guiding layer and then escapes the light guiding layer from a plurality of micro optical structures, e.g. micro cavities, that may be formed on the transparent plastic board using laser beams or molding technologies.

The light guiding layer has a lateral side facing to LED modules of the first LED light bar for guiding light of the LED modules to the diffusion layer via the light guiding layer and then to escape from a front side of the optical guiding module.

The light diffusion layer is used for diffusing light so that the light would not look too hash for human eyes, e.g. to soften the output light and to avoid users see a series of strong light points.

In addition, the light guiding layer and the light diffusion layer are fixed together as an assembly module before being placed in the surrounding border. With such design, it is easy to assembly the final product by placing all components together. For example, when the light guiding layer and the light diffusion layer are fixed together as an assembly module, a manufacturer, even a distributor or a customer, may easily place these components together, instead of needing to positioning, aligning these components.

The back cover is fixed to the heat sink frame pressing a back side of the optical guiding module. The term ‘pressing’ refers to directly or indirectly providing a force on the back side of the optical guiding module. The back side is opposite to a front side where light is output.

In some embodiments, the frame bars are mainly elongated metal bars. Some additional components like plastic, rubber components may also be added.

In some embodiments, the external surface of the heat sink frame has horizontal ripple structures. Such horizontal ripple structures increase rigidity of the panel light apparatus. Such horizontal ripple structures also enhance heat dissipation effect.

Specifically, the horizontal ripple structures may be composed of a series of concave and convex structures on the external surface of frame bars. In the example of a rectangular panel light apparatus, there are four frame bars defining a surrounding border that has a front side for light to emit and a back side to connect to a driver. In such example, the external surfaces are the four lateral surfaces of the four frame bars facing outwardly and substantially perpendicular to the front side and the back side. The term horizontal in the horizontal ripple structures refers that convex and concave structures are substantially perpendicular to the front side and the back side.

There is another type of example. The external surface of the frame bars is disposed with vertical ripple structures. In such embodiments, the convex and concave structures on the surfaces of the frame bars are parallel to the front side and the back side.

In some embodiments, the optical guiding module has a clip at a corner for fixing the light guiding layer to the light diffusion layer. The clips may be made of a plastic element or any other elastic component for pressing the light guiding layer and the light diffusion layer as an assembly module. The clip may also be a tape using glues to attach on surface of the light guiding layer and the light diffusion layer. In addition to the corner, there may be more than one clips for ensuring the light guiding layer fixed to the light diffusion layer as an assembly module. In other words, manufacturers or users may take one such assembly module without need to align or stack the light guiding layer to the light diffusion layer and place such assembly module in a heat sink frame.

Besides, in some embodiments, the corner may be processed to have a chamfer for preventing damage. Such chamfer may also help positioning, e.g. only one chamfer in a specific corner to fit in a slot of the heat sink frame. With such design, a light entrance side of the light guiding layer is ensured to face to the first LED light bar.

In some embodiments, the optical guiding module may further include a reflective layer on a back side of the optical guiding module. In such case, the reflective layer may be integrated with the light guiding layer and the light diffusion layer to form an assembly module. Please be noted that in some other embodiments, the surface of the light guiding layer is processed for soften light and the light diffusion layer may be reduced. Other features described in this specification may be integrated with such case or similar cases as another inventive solutions.

The reflective layer may be a white paper for reflecting light back to the front side, i.e. the desired light emitting side. Painting material may be used for replacing the white paper.

In addition, the reflective layer may be selected with elastic material, so as to ensure a pressure to fix all elements when the back cover is pressing on the reflective layer.

In some embodiments, there may be an additional elastic layer between the back cover and a back side of the optical guiding module. For example, a formed plastic sheet may be used in such case. Other material may also be applied for different cost or other design factors, e.g. safety.

In some embodiments, there may be a driver box electrically connected to the first LED light bar via the heat sink frame. The driver box contains driver components for converting an external power source to a driving current to the first LED light bar. The driver box may have four lateral walls and a top cover. In some case, there is a bottom cover to be attached to the back cover of the panel light apparatus. In some other case, the bottom cover is not existed or has a cavity and the back cover of the panel light apparatus is used as the bottom cover for the driver box.

There may be an empty space, e.g. taking 10% to 40% of total containing space of the driver box for providing better safety. Wires and driver components are disposed in the driver box.

In some embodiments, the driver box is inserted to a receiver on the back cover and the receiver is positioned away from peripheral area of the back cover. In such design, users would not directly see the driver box particularly when the panel light apparatus is installed below a ceiling. Such design also helps keep the driver box away from the LED light bar, which generates certain heat, and thus increase life span of the overall panel light apparatus.

In some embodiments, the heat frame sink has an electrical terminal and a frame connector. The electrical terminal is fixed to a corresponding opposite electrical terminal for receiving an external power source. For example, there is a pre-installed wire in a ceiling for providing 110V or 220V electricity. There is an opposite electrical terminal associating to the electrical terminal disposed on the heat frame sink.

The electricity of the external power source is routed to the LED modules of the first LED light bar via the frame electrical connector. The frame electrical connector may be a pre-installed wire or a metal strip for guiding external electricity and/or control signal to the first LED light bar. If there is another LED light bar or more LED light bars as explained as follows, such frame electrical connectors help connect all these electrical components to form a close loop. Users only need to plug the LED light bar into the heat sink frame, and the heat sink frame provides both structure positioning and electricity providing functions.

In some embodiments, the frame electrical connector is a metal rigid bar fixed on the frame bar.

In some embodiments, the frame electrical terminal is a detachable socket structure. In such case, users may easily plug an external electricity wire with the opposite electrical terminal into the detachable socket structure. When users want to replace the panel light apparatus, users just need to unplug the external electricity wire away from the detachable socket structure. The socket may be provided on the external electricity wire and the frame electricity terminal may be a male pin to be connected to the associated socket.

In some embodiments, the frame electrical terminal is a one way plugging structure that is difficult to be detached by hands after connecting to the external power source. For example, a reverse hook may be disposed so that it is easy to install but difficult to un-install the panel light apparatus to satisfy certain safety requirements.

In some embodiments, there may be a second LED light bar disposed at an opposite side of the first LED light bar. An electrical connector of the frame bar that is intermediate to the first LED light bar and the second LED light bar provides electricity connection between the first LED light bar and the second LED light bar. For a rectangular panel light apparatus example, the four frame bars are named ‘A’, ‘B’, ‘C’, ‘D’ in sequence. The frame bars ‘A’ and ‘C’ are installed with LED light bars and the ‘B’ or ‘D’ which is intermediate frame bar between the two LED light bars may be installed with electrical connector for electrically connecting the two LED light bars. The two LED light bars may be electrically connected in series.

In some embodiments, there may be a control signal channel, an electrical loop for sending control signals. The control signal channel may be partly or all made of connectors pre-installed on the heat sink frame. No additional wires need to be prepared in such case to enhance manufacturing convenience.

In some embodiments, there are a first type of LED components and a second type of LED components in the first LED light bar, the first type of LED components and the second type of LED components have different color temperature characteristics. There may be a third type of LED components or more for providing a different light characteristic, e.g. different colors, to provide a mixed effect of the panel light apparatus.

In some embodiments, the frame bar has an installation groove for inserting and positioning the first LED light bar. The panel light apparatus may further include a fixing bar. The fixing bar and the frame bar together clip the first LED light bar in opposite directions.

In some embodiments, the fixing bar has an elastic component for pressing the first LED light bar from a lateral direction so that the first LED light bar keeps a predetermined distance from the light guiding layer. Such elastic component may be sprint or elastic clips or other components for providing such function mentioned above.

In some embodiments, the fixing bar is further fixed to the frame bar with an additional fastener, e.g. screws.

### BRIEF DESCRIPTION OF DRAWINGS

FIG. 1 illustrates major components of an embodiment of a panel light apparatus.

FIG. 2A is a side view illustrating spatial relation among components in an embodiment.

FIG. 2B is a top view illustrating spatial relation among components in an embodiment.

FIG. 3 illustrates LED electricity connection in an embodiment.

FIG. 4 illustrates electrical connector fixed on the heat sink frame embodiment.

FIG. 5 illustrates examples for implementing plugging structures and related components in two LED light bars.

FIG. 6A illustrates a fixing bar.

FIG. 6B illustrates how the fixing bar works with a frame bar to fix a LED light bar to face to a light guiding layer.

FIG. 7 illustrates a structure of an optical guiding module.

FIG. 8 illustrates a driver box example.

FIG. 9A illustrates fixing a driver box to a back cover of a panel light apparatus embodiment.

FIG. 9B illustrates fixing the driver box to the back cover in FIG. 9A.

FIG. 10 illustrates an embodiment of a light panel apparatus.

FIG. 11A illustrates a location example of a driver box and a back cover.

FIG. 11B illustrates another location example of a driver box and a back cover.

FIG. 12 illustrates another embodiment of an external plug-in module.

FIG. 13 illustrates electricity relation among components in an embodiment.

FIG. 14 illustrates using clips in a panel light apparatus.

FIG. 15A illustrates another type of clips that embed a light bar.

FIG. 15B illustrates a side sectional view of FIG. 15A.

FIG. 16 illustrates a sectional view of a part of a light diffusion layer.

FIG. 17 illustrates a film type light diffusion layer fixed to a light guiding layer.

FIG. 18 illustrates another fixing structure for fixing the light guiding layer and the light diffusion layer as a single part.

FIG. 19A Illustrates a back cover with convex parts.

FIG. 19B illustrates the convex parts of a back cover pressing an optical guiding module.

FIG. 20 illustrates an enlarged view of a partial part in an embodiment of a panel light apparatus.

FIG. 21 illustrates a bright point problem caused by improper distance between components.

FIG. 22 illustrates additional components that may be used for enhancing the panel light apparatus embodiment.

FIG. 23A illustrates a first example of a LED light bar.

FIG. 23B illustrates a second example a LED light bar.

FIG. 23C illustrates using two LED light bars for constructing a color temperature adjustment device.

FIG. 24 illustrates connecting two LED components with different color temperatures.

FIG. 25 illustrates a panel light apparatus embodiment with a supplemental electronic device.

FIG. 26A illustrates a first example attaching the supplemental electronic device to the heat sink frame.

FIG. 26B illustrates a second example attaching the supplemental electronic device to the heat sink frame.

FIG. 26C illustrates a third example attaching the supplemental electronic device to the heat sink frame.

FIG. 27 illustrates another embodiment for integrating an external battery device.

FIG. 28 illustrates sharing components among multiple panel light apparatuses.

FIG. 29 illustrates a multi-type connector structure examples in a panel light apparatus embodiment.

FIG. 30 illustrates a different fixing device example in a panel light apparatus embodiment.

FIG. 31 illustrates another fixing device example in a panel light apparatus embodiment.

FIG. 32 illustrates an enlarged diagram showing relation between a station and a fixing device example.

FIG. 33 illustrates fixing the multi-type connector structure to a fixing bar.

FIG. 34 illustrates using multi-type connector structure to combine another panel light apparatus.

FIG. 35 illustrates using glues to fix four layers as an optical guiding module.

FIG. 36 illustrates a back cover with clips for fixing layers of the optical guiding module.

### DETAILED DESCRIPTION

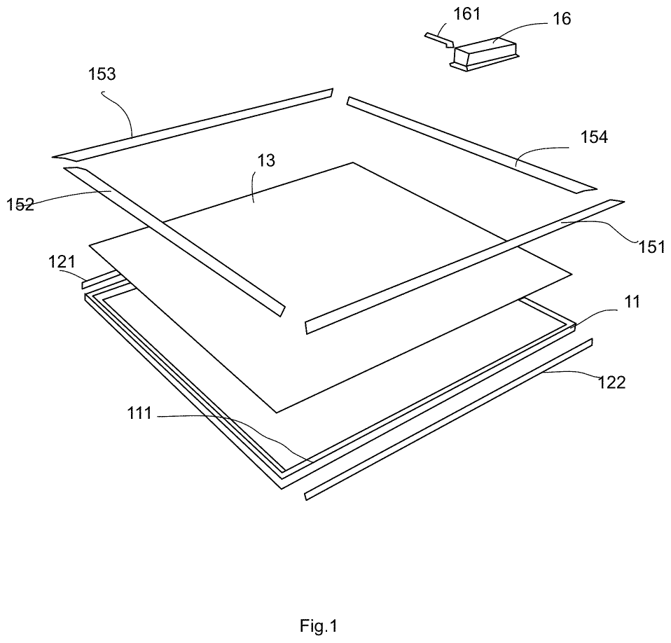

Please refer to FIG. 1. FIG. 1 illustrates major components of an embodiment of a panel light apparatus.

In FIG. 1, a LED light apparatus has a heat sink frame 11. The heat sink frame 11 has four frame bars like the one frame bar 111. In this example, there are two LED light bars 121, 122 to be installed to the heat sink frame 11. The heat sink frame 11 defines a surrounding border, the inner rectangular shape, for storing an optical guiding module 13.

Four fixing bars 151, 152, 153, 154 are used for pressing the optical guiding module 13 so that the optical guiding module 13 is clipped between the four fixing bars 151, 152, 153, 154 and the heat sink frame 11.

In this example, an external driver box 16 contains driver components for converting an external power source like a 110V or 220V electricity to a driving current for the two LED light bars 121, 122. The driver box 16 connects the two LED light bars 121, 122 via an opposite terminal 161, which connects to an electrical terminal that is further electrically connected to electrical connectors in the heat sink frame 11 for connecting to the two LED light bars 121, 122.

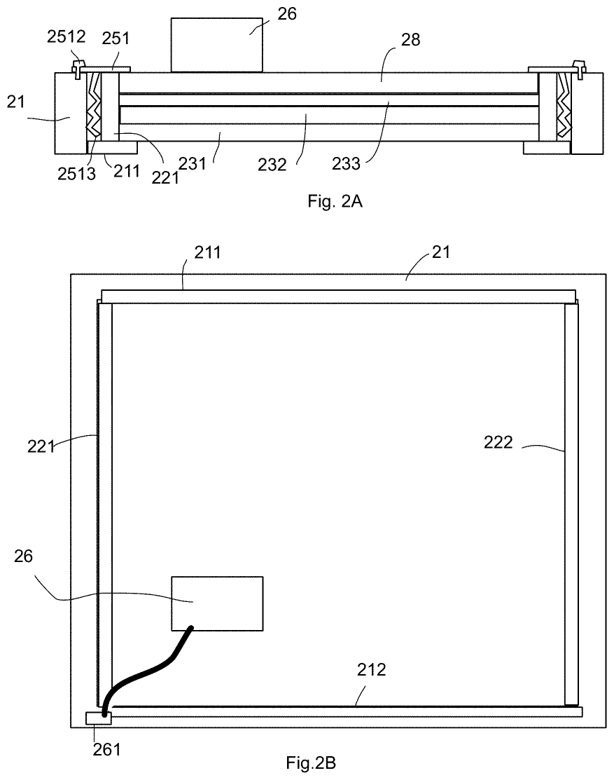

Next, please refer to FIG. 2A and FIG. 2B. FIG. 2A is a side view illustrating spatial relation among components in an embodiment. FIG. 2B is a top view illustrating spatial relation among components in an embodiment.

In FIG. 2A, a driver box is fixed to a back cover 28. The back cover 28 presses an optical guiding module. The optical guiding module has a reflective layer 233, a light guiding layer 232 and a light diffusion layer 231. In some other case, there may be an additional elastic layer between the back cover 28 and the reflective layer 233 for ensuring the layers of the light guiding module closely stick to each other.

In this example, a LED light bar 221 is clipped by a fixing bar 251 and a bottom part 211 of a frame bar 21 of a heat sink frame. In addition, there is an elastic component 2513. The elastic component 2513 is fixed to the fixing bar 251 for pressing the LED light bar 221 to align to a predetermined position with respect to a light guiding layer 232. The light emitted from LED modules of the LED light bar 221 enters the light guiding layer 232 and then moves to light diffusion layer 231 and then escapes from a front cover of the optical guiding module. Some light transmits upwardly and reflected by a reflective layer 233 back to the light guide layer 232.

The driver box 26 is fixed to the cover 28 and connects to the heat sink layer via an opposite electrical terminal, which is inserted to an electrical terminal 261 of the heat sink frame.

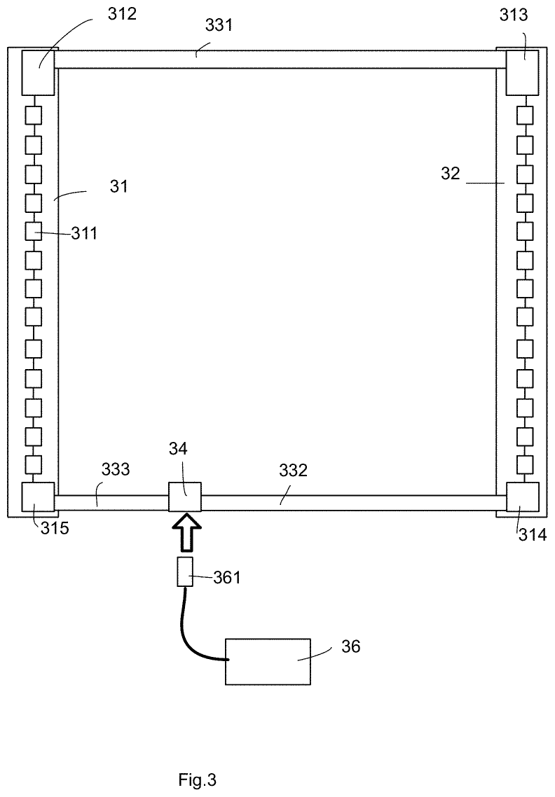

Please refer to FIG. 3. FIG. 3 illustrates LED electricity connection in an embodiment.

In FIG. 3, there are electrical connectors 331, 332, 333 disposed in the heat sink frame for helping transmitting electricity and even control signals for the two LED light bars 31, 32. In this example, the LED light bar 31 has multiple LED modules connected in series. The two LED light bars 31, 32 have first plugging structures 312, 313, 314, 315 to be plugged to second plugging structures of electrical connectors 331, 332, 333 in the heat sink frame.

An electricity terminal 34 is also disposed in the heat sink frame for receiving a driving current generated by a driver box 36. The driver box 36 is connected to the two LED light bars 31, 32 by plugging an opposite electrical terminal 361 to the electrical terminal 34.

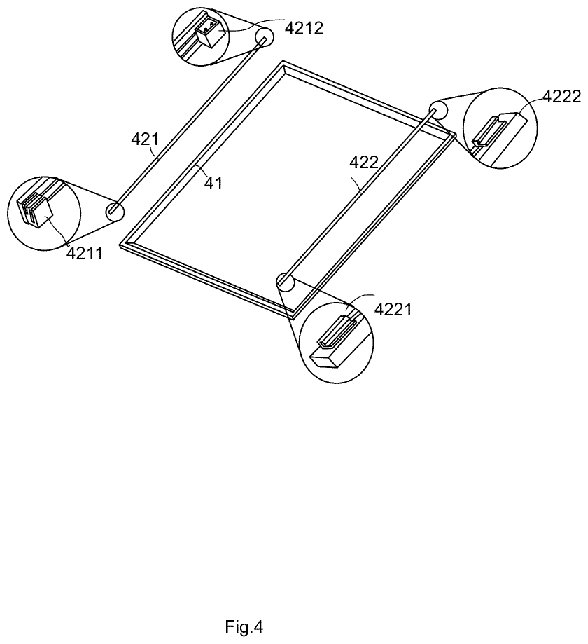

Please refer to FIG. 4. FIG. 4 illustrates electrical connector fixed on the heat sink frame embodiment. Two electrical connectors 421, 422 fixed on a heat sink frame 41 are illustrated. At two ends of each electrical connector 421, 422, there are two connectors 4211, 4212, 4221, 4222 that may be plugged. In this example, two LED light bars are plugged to the electrical connectors 421, 422 to be connected in series and to get a driving current.

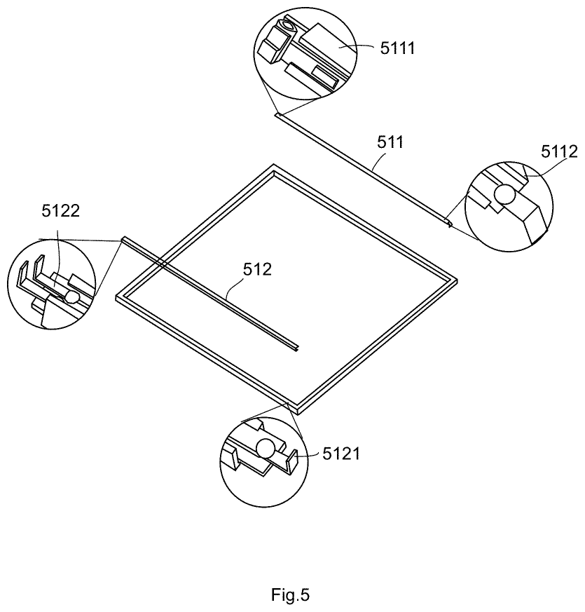

Please refer to FIG. 5. FIG. 5 illustrates examples for implementing plugging structures and related components in two LED light bars.

In FIG. 5, there are two LED light bars 511, 512. The two LED light bars 511, 512 have plugging structures 5121, 5122, 5111, 5112 at two ends to be connected to associated plugging structures as illustrated in FIG. 4. Other plugging structures may be used based on different design needs.

In a more general embodiment, a panel light apparatus includes a heat sink frame, a first LED light bar, an optical guiding module and a back cover. The panel light apparatus may be installed below a ceiling, attach to a wall or installed in other applications. The heat sink frame defines light output shape, e.g. a rectangular light output shape. The thickness of the panel light apparatus is usually smaller than width of the light output shape. Usually, the thickness of the panel light apparatus is smaller than normal downlight devices so that the panel light apparatus does not need an additional installation cavity, e.g. in a ceiling.

The heat sink frame includes a plurality of frame bars forming a surrounding border. For example, if the heat sink frame has a rectangular shape, there are four frame bars at four sides. The four frame bars form a rectangular surrounding border. Please be noted that the frame bar may also be made of one or multiple frame bars to form different shapes, e.g. circular, ellipse, two connected rectangular shapes like a digit ‘8’ or other shapes.

The first LED light bar has a first plugging structure to be plugged to a second plugging structure on an inner side of one of the frame bars. For example, if the panel light apparatus is a rectangular shape panel light, there are four frame bars as mentioned above. One frame bar is disposed with a second plugging structure associating with a first plugging structure of a LED light bar. The first plugging structure may be a male pin when the second plugging structure may be a female socket, and vice versa. The first plugging structure and the second plugging structure may provide both structural connection and electricity connection. In other words, the first LED bar may receive electricity from the connection of the first plugging structure and the second plugging structure. Meanwhile, the first LED bar is fixed to the heat sink frame by the connection of the first plugging structure and the second plugging structure. Please be noted that the plugging structure may have various shapes, e.g. elastic clips, hooks and associates connecting structures.

Besides, the first LED light bar is a major heat source, and heat generated from the first LED light bar is transmitted to the frame bars of the heat sink frame.

The optical guiding module is placed in the surrounding border. For example, the surrounding border is a rectangular shape and the optical guiding module is also a similar rectangular shape but with a smaller size. The optical guiding module is placed in the enclosing border of the heat sink frame.

The optical guiding module may have a light diffusion layer and a light guiding layer. The light guiding layer may be a transparent plastic board a plurality of micro structures for guiding light received from a lateral side of the transparent plastic board to route in the light guiding layer and then escapes the light guiding layer from a plurality of micro optical structures, e.g. micro cavities, that may be formed on the transparent plastic board using laser beams or molding technologies.

The light guiding layer has a lateral side facing to LED modules of the first LED light bar for guiding light of the LED modules to the diffusion layer via the light guiding layer and then to escape from a front side of the optical guiding module.

The light diffusion layer is used for diffusing light so that the light would not look too hash for human eyes, e.g. to soften the output light and to avoid users see a series of strong light points.

In addition, the light guiding layer and the light diffusion layer are fixed together as an assembly module before being placed in the surrounding border. With such design, it is easy to assembly the final product by placing all components together. For example, when the light guiding layer and the light diffusion layer are fixed together as an assembly module, a manufacturer, even a distributor or a customer, may easily place these components together, instead of needing to positioning, aligning these components.

The back cover is fixed to the heat sink frame pressing a back side of the optical guiding module. The term ‘pressing’ refers to directly or indirectly providing a force on the back side of the optical guiding module. The back side is opposite to a front side where light is output.

In some embodiments, the frame bars are mainly elongated metal bars. Some additional components like plastic, rubber components may also be added.

In some embodiments, the external surface of the heat sink frame has horizontal ripple structures. Such horizontal ripple structures increase rigidity of the panel light apparatus. Such horizontal ripple structures also enhance heat dissipation effect.

Specifically, the horizontal ripple structures may be composed of a series of concave and convex structures on the external surface of frame bars. In the example of a rectangular panel light apparatus, there are four frame bars defining a surrounding border that has a front side for light to emit and a back side to connect to a driver. In such example, the external surfaces are the four lateral surfaces of the four frame bars facing outwardly and substantially perpendicular to the front side and the back side. The term horizontal in the horizontal ripple structures refers that convex and concave structures are substantially perpendicular to the front side and the back side.

There is another type of example. The external surface of the frame bars is disposed with vertical ripple structures. In such embodiments, the convex and concave structures on the surfaces of the frame bars are parallel to the front side and the back side.

In some embodiments, the optical guiding module has a clip at a corner for fixing the light guiding layer to the light diffusion layer. The clips may be made of a plastic element or any other elastic elements for pressing the light guiding layer and the light diffusion layer as an assembly module. The clip may also be a tape using glues to attach on surface of the light guiding layer and the light diffusion layer. In addition to the corner, there may be more than one clip for ensuring the light guiding layer fixed to the light diffusion layer as an assembly module. In other words, manufacturers or users may take one such assembly module without need to align or stack the light guiding layer to the light diffusion layer and place such assembly module in a heat sink frame.

Besides, in some embodiments, the corner may be processed to have a chamfer for preventing damage. Such chamfer may also help positioning, e.g. only one chamfer in a specific corner to fit in a slot of the heat sink frame. With such design, a light entrance side of the light guiding layer is ensured to face to the first LED light bar.

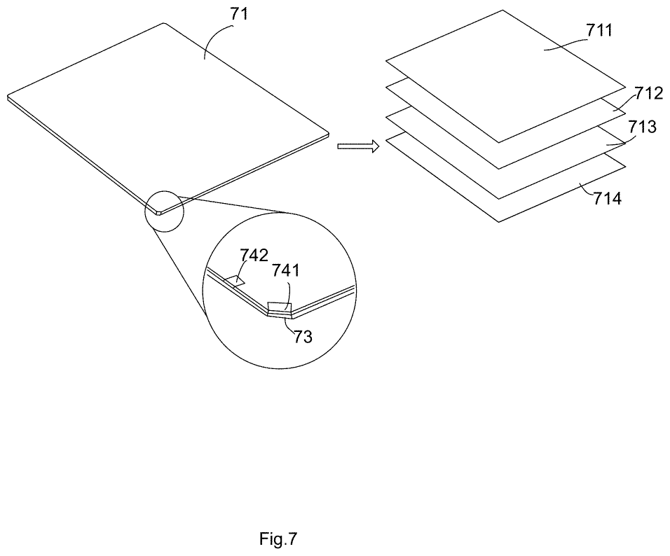

Please refer to FIG. 7. FIG. 7 illustrates a structure of an optical guiding module.

In FIG. 7, an optical guiding module 71 is processed to have a chamfer 73 at its corner. There are two clips 741, 742 for fixing an elastic layer 711, a reflective layer 712, a light guiding layer 713 and a light diffusion layer 714 together as an assembly module.

In some embodiments, the optical guiding module may further include a reflective layer on a back side of the optical guiding module. In such case, the reflective layer may be integrated with the light guiding layer and the light diffusion layer to form an assembly module. Please be noted that in some other embodiments, the surface of the light guiding layer is processed for soften light and the light diffusion layer may be reduced. Other features described in this specification may be integrated with such case or similar cases as another inventive solutions.

The reflective layer may be a white paper for reflecting light back to the front side, i.e. the desired light emitting side. Painting material may be used for replacing the white paper.

In addition, the reflective layer may be selected with elastic material, so as to ensure a pressure to fix all elements when the back cover is pressing on the reflective layer.

In some embodiments, there may be an additional elastic layer between the back cover and a back side of the optical guiding module. For example, a formed plastic sheet may be used in such case. Other material may also be applied for different cost or other design factors, e.g. safety.

In some embodiments, there may be a driver box electrically connected to the first LED light bar via the heat sink frame. The driver box contains driver components for converting an external power source to a driving current to the first LED light bar. The driver box may have four lateral walls and a top cover. In some case, there is a bottom cover to be attached to the back cover of the panel light apparatus. In some other case, the bottom cover is not existed or has a cavity and the back cover of the panel light apparatus is used as the bottom cover for the driver box.

There may be an empty space, e.g. taking 10% to 40% of total containing space of the driver box for providing better safety. Wires and driver components are disposed in the driver box.

In some embodiments, the driver box is inserted to a receiver on the back cover and the receiver is positioned away from peripheral area of the back cover. In such design, users would not directly see the driver box particularly when the panel light apparatus is installed below a ceiling. Such design also helps keep the driver box away from the LED light bar, which generates certain heat, and thus increase life span of the overall panel light apparatus.

In some embodiments, the heat frame sink has an electrical terminal and a frame connector. The electrical terminal is fixed to a corresponding opposite electrical terminal for receiving an external power source. For example, there is a pre-installed wire in a ceiling for providing 110V or 220V electricity. There is an opposite electrical terminal associating to the electrical terminal disposed on the heat frame sink.

The electricity of the external power source is routed to the LED modules of the first LED light bar via the frame electrical connector. The frame electrical connector may be a pre-installed wire or a metal strip for guiding external electricity and/or control signal to the first LED light bar. If there is another LED light bar or more LED light bars as explained as follows, such frame electrical connectors help connect all these electrical components to form a close loop. Users only need to plug the LED light bar into the heat sink frame, and the heat sink frame provides both structure positioning and electricity providing functions.

In some embodiments, the frame electrical connector is a metal rigid bar fixed on the frame bar.

In some embodiments, the frame electrical terminal is a detachable socket structure. In such case, users may easily plug an external electricity wire with the opposite electrical terminal into the detachable socket structure. When users want to replace the panel light apparatus, users just need to unplug the external electricity wire away from the detachable socket structure. The socket may be provided on the external electricity wire and the frame electricity terminal may be a male pin to be connected to the associated socket.

In some embodiments, the frame electrical terminal is a one way plugging structure that is difficult to be detached by hands after connecting to the external power source. For example, a reverse hook may be disposed so that it is easy to install but difficult to un-install the panel light apparatus to satisfy certain safety requirements.

In some embodiments, there may be a second LED light bar disposed at an opposite side of the first LED light bar. An electrical connector of the frame bar that is intermediate to the first LED light bar and the second LED light bar provides electricity connection between the first LED light bar and the second LED light bar. For a rectangular panel light apparatus example, the four frame bars are named ‘A’, ‘B’, ‘C’, ‘D’ in sequence. The frame bars ‘A’ and ‘C’ are installed with LED light bars and the ‘B’ or ‘D’ which is intermediate frame bar between the two LED light bars may be installed with electrical connector for electrically connecting the two LED light bars. The two LED light bars may be electrically connected in series.

In some embodiments, there may be a control signal channel, an electrical loop for sending control signals. The control signal channel may be partly or all made of connectors pre-installed on the heat sink frame. No additional wires need to be prepared in such case to enhance manufacturing convenience.

In some embodiments, there are a first type of LED components and a second type of LED components in the first LED light bar, the first type of LED components and the second type of LED components have different color temperature characteristics. There may be a third type of LED components or more for providing a different light characteristic, e.g. different colors, to provide a mixed effect of the panel light apparatus.

In some embodiments, the frame bar has an installation groove for inserting and positioning the first LED light bar. The panel light apparatus may further include a fixing bar. The fixing bar and the frame bar together clip the first LED light bar in opposite directions.

In some embodiments, the fixing bar has an elastic component for pressing the first LED light bar from a lateral direction so that the first LED light bar keeps a predetermined distance from the light guiding layer. Such elastic component may be sprint or elastic clips or other components for providing such function mentioned above.

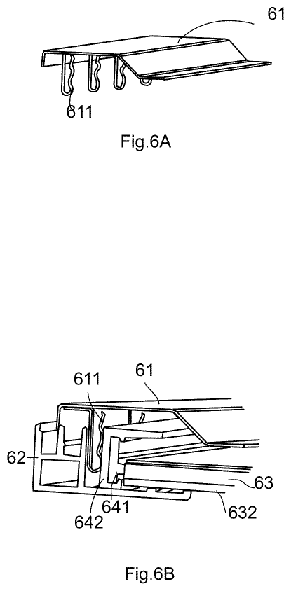

Please refer to FIG. 6A and FIG. 6B. FIG. 6A illustrates a fixing bar. FIG. 6B illustrates how the fixing bar works with a frame bar to fix a LED light bar to face to a light guiding layer.

In FIG. 6A and FIG. 6B, a fixing bar 61 is an elongated sheet. There is an elastic component 611 installed on the fixing bar 61. In this example, the elastic component 611 is an elastic curved metal wire.

In FIG. 6B, when the fixing bar 61 is installed, the fixing bar 61 and the frame bar 61 of the heat sink frame together fix a LED light bar 642. Furthermore, the elastic component 611 presses the LED light bar 642 from a lateral side to ensure the LED components 641 on the LED light bar 642 to keep a desired distance to the light guiding layer 63 of an optical guiding module. The optical guiding module may further include a light diffusion layer 632.

In some embodiments, the fixing bar is further fixed to the frame bar with an additional fastener, e.g. screws.

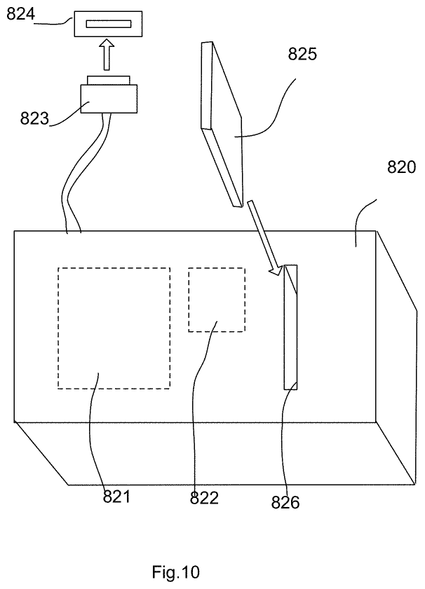

Please refer to FIG. 10, which illustrates a driver box embodiment of a panel light apparatus. In FIG. 10, the panel light apparatus has a driver circuit 821, an interface circuit 822 and a slot 826. The driver circuit 821, the interface circuit 822 and the slot 825 are disposed in a driver housing 820. In this example, the driver housing is a box shape device.

An external plug-in module 825 may be inserted into the slot 826 to connect the external plug-in module 825 to the interface circuit 822.

In addition, the driver box has a wire with an end terminal 823 to be plugged into a corresponding socket 824 disposed on a heat sink frame as explained above.

According to an embodiment, a panel light apparatus includes a heat sink, a first LED light bar, an optical guiding module, a back cover and a driver box.

There may be more than one LED light bar, and some examples are explained as follows. The heat sink frame includes multiple frame bars forming a surrounding border. For example, four frame bars may be fixed as a frame, defining a rectangular surrounding border. Circular frame bars may also be used for defining a circular surrounding, e.g. a circular shape panel light apparatus. The frame bar may have a curved shape, in addition to an elongated line bar shape.

The first LED light bar is fixed on an inner side of one of the frame bars for fixing the first LED light bar to the heat sink frame. Heat of the LED light bar may be transmitted to the heat sink frame. The frame bar may be made of metal material, like aluminum, or other heat conductive plastic material, like PC. There may be multiple LED modules mounted on the first LED light bar. These LED modules may be connected in series, or in series and in parallel, or multiple separate modules that may be driven separately, e.g. to turn on or turn off separately.

The optical guiding module is placed in the surrounding border. The optical guiding module includes a light diffusion layer and a light guiding layer. A lateral side of the light guiding layer faces to LED modules of the first LED light bar for guiding light of the LED modules to the diffusion layer via the light guiding layer and then to escape from a front side of the optical guiding module.

The light guiding layer and the light diffusion layer may be fixed together as an assembly module before being placed in the surrounding border.

The back cover is fixed to the heat sink frame directly or indirectly pressing a back side of the optical guiding module. For example, an elastic layer may be placed between the back cover and the light guiding module.

The driver box includes a driver circuit, an interface circuit, a slot and a driver housing.

The driver circuit is used for converting an external power source to a driver current for the LED modules. For example, a 110V or 220V alternating current is converted to a direct current with proper voltage as a driving current for the LED modules of the first LED light bar.

The interface circuit is connected to the driver circuit. In addition to supply current to the LED modules, the driver circuit may also supply first module electricity to an external plug-in module. The external plug-in module is inserted into the slot for electrically connected to the interface circuit. The driver housing containing the driver circuit, the interface circuit and the slot. The shape of the driver housing may be a box style container.

Such design is particularly helpful because manufacturer may assemble different components to meet different requirements. Furthermore, the driver box may be inserted with different modules to expand the capacity of the driver box. For example, the external plug-in module may be a wireless control module, like in Bluetooth, Wi-Fi, Zig-bee, W3 or any other communication protocols. The interface circuit translates an external command and act correspondingly to control the driver circuit or the LED modules. There are various other ways to use this extension slot and are explained with examples as follows.

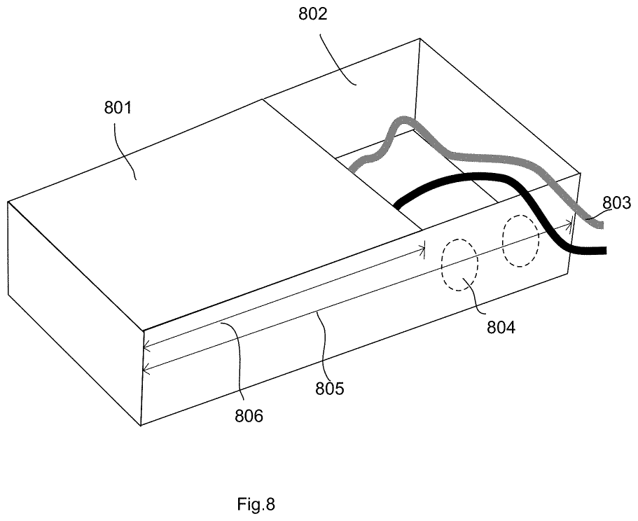

Please refer to FIG. 8, which illustrates a driver box example. In FIG. 8, the driver box has a circuit container 801 and a wiring container 802. The driver circuits are placed in the circuit container 801 and protected with a metal cover. The size 806 of the circuit container 801 with respect to the total size 805 of the driver box is between 40% to 80%. Such configuration ensures the wiring 803, e.g. via installation holes 804, more reliable and safer.

In some embodiments, the driver box has a wire and an end terminal attached at end of the wire. The end terminal may be plugged to a corresponding socket installed on the heat sink frame. In other words, in such case, manufacturers may choose a driver box with specific requirements and just plug the end terminal of the driver box to the corresponding socket on the heat sink frame to assemble the driver box and the heat sink frame. For example, driver boxes may have a U.S. type and a European type. Manufacturers just prepare corresponding driver box and plug the driver box to the main body of the panel light apparatus. This step may be even left for customers to assemble the panel light apparatus.

To prevent error assembling causing accident, there may be different types of sockets to be installed to the heat sink frame corresponding to different LED light bars for receiving different electricity input parameters from different driver boxes for preventing connection between inconsistent LED light bars and driver boxes. For example, the socket shipped to U.S. for 110V power input may have a square socket style and the socket shipped to European for 220V power input may have a circular socket style on the heat sink frame.

In some embodiments, there may be multiple types of the external plug-in modules providing different functions to be plugged into the slot. For example, the external plug-in module may be a wireless communication module for receiving an external command, e.g. from a mobile phone. The external plug-in module may be a day-light sensor connected to a detector for determining whether it is time to automatically turn on or turn off the panel light apparatus. The external plug-in module may be a camera, a speaker, a fire alarm module, or any functional component. The interface circuit may be designed for automatically determine which kind of external plug-in module is plugged into the slot, e.g. by checking an input pin, or parsing a serial command.

In some embodiments, users may need different types of wireless protocols to control the panel light apparatus. For example, users may have controllers of Wi-Fi, Bluetooth, Zig-bee, Z-wave, and a corresponding wireless module may be designed as the external plug-in module. The interface circuit translates external commands from different wireless protocols into unified commands for controlling the panel light apparatus.

In addition to receive commands from outside, the interface may even be coded to send status or data, e.g. recorded audio data, to an external device.

In some embodiments, there is one or more jumpers disposed on the driver box for configuring the interface manually, instead of smart detection, corresponding to different types of external plug-in modules.

In some embodiments, the interface circuit controls and adjusts the driver circuit to function correspondingly, e.g. to supply electricity of different parameters, in different operation modes according to an external command received from an external plug-in module.

For example, the brightness or the color temperature may be adjusted by controlling the driver circuit to operate in different modes when driving the LED modules of the first LED light bar.

In some embodiments, there may be a detector in the driver circuit for detecting an impedance of the LED light bar for automatically adjusting the driving current of the driver circuit supplying to the LED light bar. In other words, even the first LED light bar, or with other LED light bars, are disposed with different number or different types of LED modules, the same driver box may be used. In other words, the same driver circuit adjusts output of the electricity for matching different LED light bar requirements. This saves a lot of storage cost and brings a lot of convenience and safety.

In some embodiments, the external plug-in module itself brings setting information. For example, the external plug-in module may contain routing wires to re-route electricity signals to the interface circuit. Different external plug-in modules are disposed with different routing wires corresponding to different operation modes. In other words, the external plug-in module may be a simple instruction provider for indicating the driver circuit a designated operation mode. This is usually more convenient and safer compared with jumpers. For example, the external plug-in module may be designed as a card shape. For different market or different operation modes, manufacturers may prepare different cards to be plugged into the slot, to determine the operation mode of the panel light apparatus.

In some embodiments, the driver circuit may have multiple separable circuit modules that may be activated separately. For example, for heavy loading LED modules with brighter output, more circuit modules are activated for providing more current.

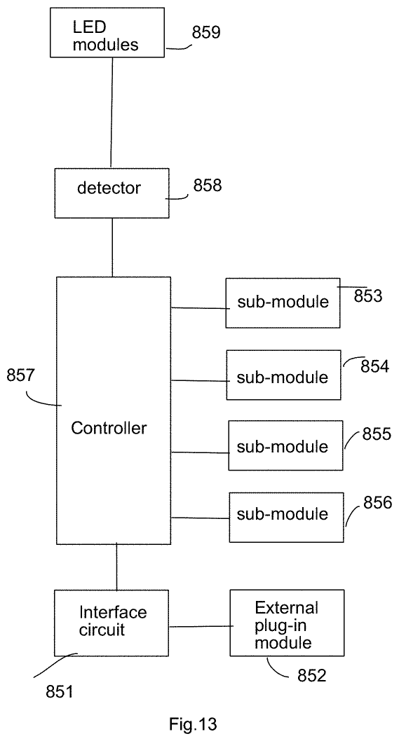

Please refer to FIG. 13. In FIG. 13, there are multiple sub-modules 853, 854, 855, 856 that may be activated separately depending on different settings. For example, the interface circuit 851 may receive a setting from an external plug-in module 852 for instructing the controller 857 of the driver circuit to determine which of the sub-modules 853, 854, 855, 856 to be activated.

In addition, there may be a detector 858 for detecting impedance of the LED modules 859. The detected result is sent to the controller to dynamically adjust output of the driver circuit smartly.

In some embodiments, the slot may be a standard interface, e.g. as a USB slot. In such case, all peripheral devices complying with USB standards may be installed to the driver box, to get power supply or to provide data to the driver box.

In some embodiments, the external plug-in module may further have an extension slot for plugging in another external plug-in module. In other words, multiple external plug-in modules may be connected in series into the slot of the driver box. In one design, the external plug-in module, plugging in the slot of the driver box, may have a slot and an interface circuit like the driver box for connecting to anther external plug-in module.

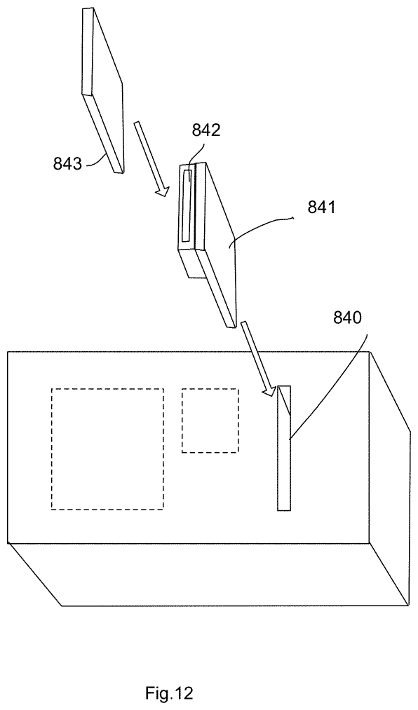

Please refer to FIG. 12. In FIG. 12, a first external plug-in module 841 may be inserted to the slot 840 as mentioned above. In addition, the first external plug-in module 841 may have another slot 842, that may have the same interface as the slot 840 or not, for receiving another external plug-in module 843. This provides more flexibility on designing the external plug-in devices.

In some embodiments, the external plug-in module may contain a battery. When the battery is connected to the driver box, the LED light bar receives the driving current from the battery. For example, the interface circuit may check whether there is power supply from outside to the driver circuit. If there is no electricity now, the power of the battery is routed to the driver circuit for generating a corresponding driving current to the LED modules of the first LED light bar. As mentioned above, the slot of the driver box may be a standard slot, e.g. a USB slot. In such case, a common USB battery box may be plugged into the panel light apparatus for emergency use. When one USB batter box is out of power, another USB battery box may be replaced instantly.

In some embodiments, the heat sink frame is selectively installed with one of multiple types of routing components for different LED light bars and operation modes. For example, the same heat sink frame may be disposed with different routing connectors to its frame bars for connecting different LED light bars, e.g. some with color temperature adjustment and some with other functions and configurations. Such routing components may have different socket styles for connecting to different driver boxes, e.g. a circular style socket or a rectangular style socket.

In some embodiments, these routing components that contain insulation parts and conductive parts may be made as a module with plugging structures to be plugged to the frame bars of the heat sink frame directly. In other words, no welding or glue may be necessary in such design to enhance assembly convenience.

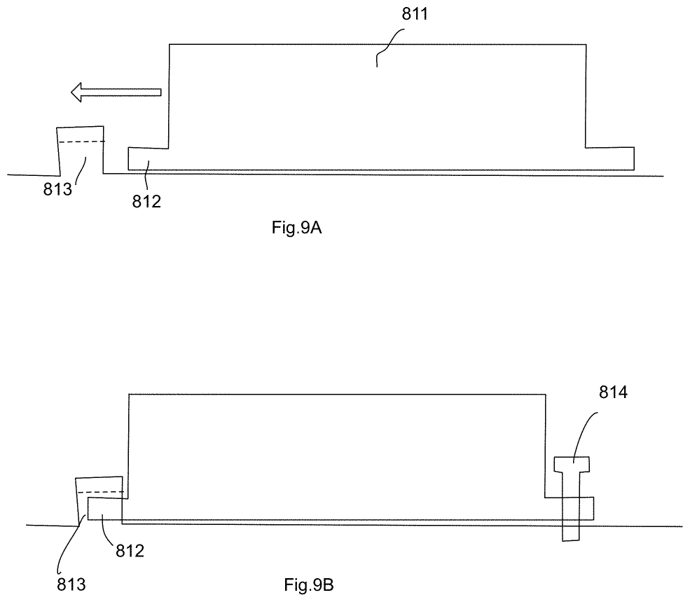

Please refer to FIG. 9A and FIG. 9B. FIG. 9A and FIG. 9B illustrate fixing a driver to a back cover of a panel light embodiment.

In FIG. 9A, the driver box has a bottom pin 812 to be plugged into a back slot 813 of a back cover. During installation, the driver box 811 is firstly inserted into the back slot 813 for positioning. Then, a screw 814 may be used for further fixing the driver box to the back cover.

In some embodiments, the driver box may have one or more bottom pins to be plugged into corresponding back slots of the back cover. Further screws may be used for fixing the driver box to the back cover to increase robustness of the panel light apparatus.

In some embodiments, there is a second LED light bar. The first LED light bar and the second LED light bar are fixed at two opposite sides of the heat sink frame. The driver box is fixed to another side, not the two opposite sides, of the heat sink frame. In other words, the driver box is kept away from the heat generation sources to extend life span of the driver circuit and the LED modules.

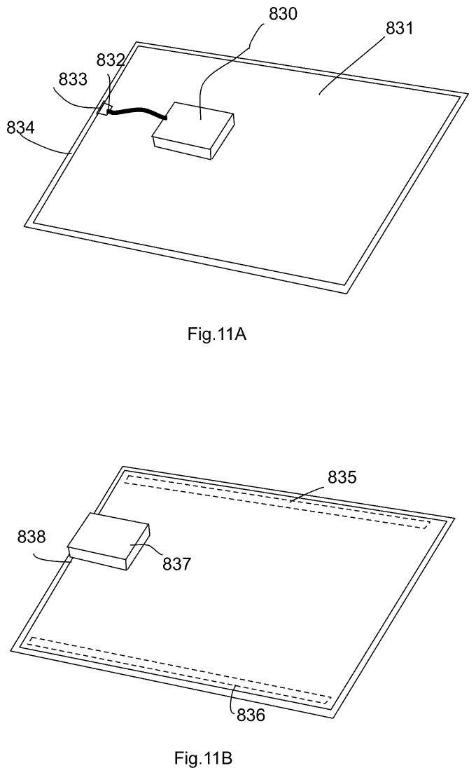

Please refer to FIG. 11B, which illustrates one example as mentioned above. In FIG. 11B, the two LED light bars 835, 836 are disposed on opposite sides of a panel light apparatus. The driver box 837 is disposed on another side 838, to keep a distance with the two heat generation sources.

In some embodiments, the driver box is fixed to the back cover away from a peripheral area of the back cover. For example, the driver box is disposed at the center of the back cover, away from where the LED modules are disposed.

Please refer to FIG. 11A, which illustrates one example mentioned above. In FIG. 11A, the driver box 830 is disposed away from peripheral area of the back cover 831. There is a wire with an end terminal 832 to be plugged to a socket 833 connected to a connector module 834 installed to the frame bar of the heat sink frame.

According to an embodiment of the present invention, a panel light apparatus includes a heat sink frame, a first LED light bar, an optical light guiding module and a back cover.

The heat sink frame includes multiple frame bars forming a surrounding border. For example, for a rectangular panel light apparatus has four frame bars forming a rectangular surrounding border.

The first LED light bar may have a first plugging structure to be plugged to a second plugging structure on an inner side of one of the frame bars for fixing the first LED light bar to the heat sink frame. The heat sink frame comprises heat dissipation material, e.g. aluminum or plastic like PC material. Heat of the LED light bar is transmitted to the heat sink frame.

The optical guiding module is placed in the surrounding border. The optical guiding module includes a light diffusion layer and a light guiding layer. A lateral side of the light guiding layer faces to LED modules of the first LED light bar for guiding light of the LED modules to the diffusion layer via the light guiding layer and then to escape from a front side of the optical guiding module.

The light guiding layer and the light diffusion layer are fixed together as a single part. The light guiding layer and the light diffusion layer are kept together without falling apart even before the single part is placed in the surrounding border. Specifically, manufacturers may take one such single part, without need to align the light guiding layer to the light diffusion layer again, and just put the single part in the surrounding border of the heat sink frame to complete the assembling of components. This saves a lot of labor work and prevents unnecessary damage, particularly to sensitive surface of optical components, like the light guiding layer. Otherwise, there may be certain protective layer, that needs to be removed first, on surface of the light guiding layer before combining the optical light guiding layer to the light diffusion layer.

The back cover is fixed to the heat sink frame for protecting the optical guiding module. The back cover may be made of a metal or a plastic material, depending on design requirements.

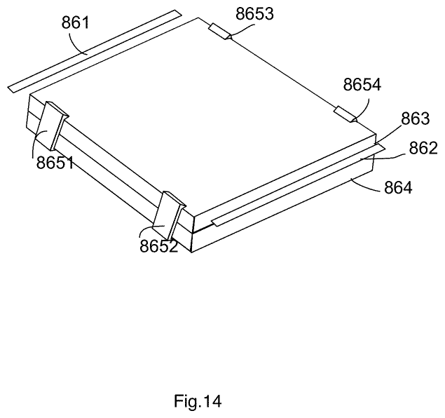

FIG. 14 illustrates using clips in a panel light apparatus. In FIG. 14, a light guiding layer 863 and a light diffusion layer 864 are fixed together as a part with clips 8651, 8652, 8653, 8654. The clips 8651, 8652, 8653, 8654 are disposed at two sides of the light guiding layer 863 and the light diffusion layer 864, away from the other two sides of the light guiding layer 863, where two LED light bars 861, 862 emit light into the light guiding layer 863.

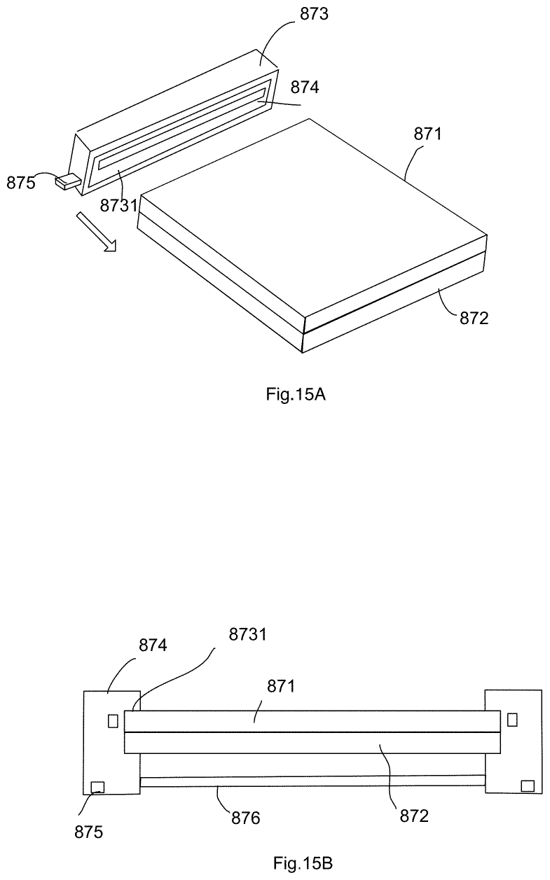

FIG. 15A and FIG. 15B illustrate another type of clips, which teaches that the clips may have various design ways.

In FIG. 15A, the light guiding layer 871 and the light diffusion layer 872 are fixed together with an elongated clip 873. The elongated clip 873 has a lens bar 874 facing to LED modules of a corresponding LED light bar. The lens bar 874 may contain a series of lens, or a lens with a lot of micro lens structures, for helping light of the LED modules more effectively enter the light guiding layer 871.

In some embodiment, the LED light module may even be embedded with the elongated clip 873, e.g. to take the position of the lens bar 874. A pluggable terminal 875 may be disposed so that the whole module, including the LED light bar and the optical guiding module of the light guiding layer 871 and light diffusion layer 872, may be assembled to the heat sink frame directly.

Such design may further reduce manufacturing complexity and cost. An elastic element 876 may be used for connecting two opposite clips, as illustrated in FIG. 15B.

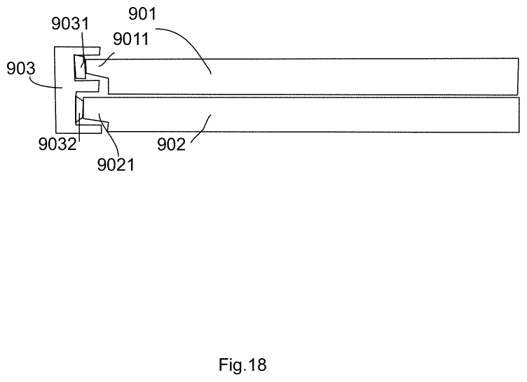

FIG. 18 illustrates another clip example. In FIG. 18, the light guiding layer 901 and the light diffusion layer 902 have cut peripheral edges 9011, 9021 to fit into the clip 903. Elastic pads 9031, 9032 are provided to prevent inconsistent shape change when the light guiding layer 901 and the light diffusion layer 902 are heated by LED modules.

The clips may provide sliding tracks for inserting the light guiding layer 901 and the light diffusion layer 902. Additional screws, glue or other fixing tools may be applied to fix the light guiding layer 901 and the light diffusion layer 902.

In some embodiments, the light diffusion layer and the light guiding layer are fixed with a transparent glue.

In some embodiments, the glue may be mixed with micro particles. Directions of light escaped out of the light guiding layer are diffused when confronting the micro particles. Specifically, such micro particles are distributed in the glue layer. When light escapes from the light guiding layer to the diffusion layer, light engages these micro particles and changes directions almost randomly when these micro particles are mixed evenly in the glue. After assembling, the glue is hardened. In some aspect, the glue may be referred to as part of the diffusion layer. With such design, the light diffusion layer may be thinner, which further decreases overall thickness of the panel light apparatus. In addition, the diffusion layer that is fixed together with the light guiding layer with the glue may even be a transparent film, just to protect the glue layer.

In some embodiments, the micro particles are plastic transparent balls. To provide better effect, the micro particles may be kept with a diameter less than 0.4 mm. A preferred range of the diameter may be within 0.01 mm to 0.4 mm.

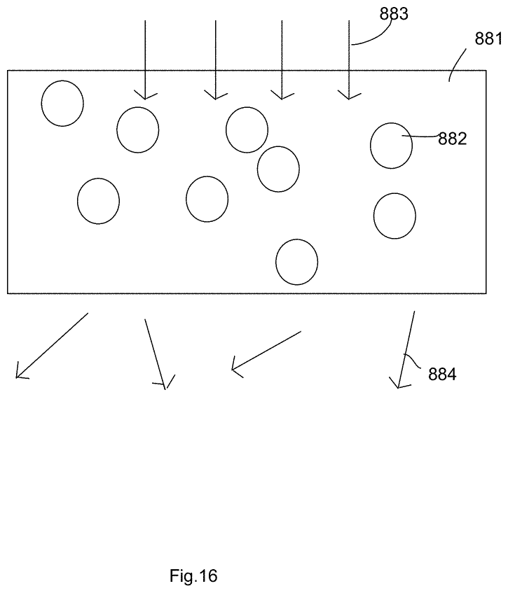

Please refer to FIG. 16, which illustrates a light diffusion layer filled with micro particles.

In FIG. 16, the light diffusion layer 881 is mixed with a lot of micro particles 862, as mentioned above. The actual number of micro particles 862 may be determined by how soften the light output is expected.

Light 883 from a light guiding layer meet these micro particles 862 and change directions almost randomly to diffusion light 884.

In some embodiments, the light guiding layer is made of PMMA (Polymethyl Methacrylate) material and the diffusion layer is a hardened glue layer containing diffusion material. In some cases, the diffusion material contains micro particles with a diameter less than 0.4 mm. For example, such micro particles may be plastic transparent balls as mentioned above.

In some embodiments, the light guiding layer and the light diffusion layer are fixed with multiple clips. These clips clip the light guiding layer the light diffusion layer at lateral sides to keep these layers to fit together as a single part.

In some embodiments, these clips include elastic components, like rubber tape, facing to the light guiding layer and the light diffusion layer. This particularly helps increase robustness of the panel light apparatus when the light guiding layer and the light diffusion layer are made of different material and cause different size increasing during being heated, like operation of the LED modules.

In some embodiments, some clips are placed at two opposite sides of the light guiding layer and the light diffusion layer. These clips are connected with elastic elements like rubber bands for forming an elastic frame so as to keep these clips to better hold the light guiding layer and the light diffusion layer together.

In some embodiments, there is a reflection layer in the light guiding module. The reflection layer and the light diffusion layer are at two sides of the light guiding layer. Specifically, the reflection layer is placed on a back side of the light guiding layer and the light diffusion layer is on a front side of the light guiding layer. The clips further fix the reflective layer and the other two layers together to form a single-part optical guiding module.

In some embodiments, there is further an elastic layer above the reflection layer. The elastic layer and the light guiding layer are at two sides of the reflection layer. With the elastic layer, when a pressing force is applied on top side of the elastic layer, the elastic layer transmits even force to the reflection layer, and then to the light guiding layer and the light diffusion layer to fit these layers more closely together.

In some embodiments, the reflective layer may be made of elastic material, thus preventing the need of an additional elastic layer as mentioned above.

In some embodiments, the back cover may have multiple convex portions directly or indirectly pressing the optical guiding module. For example, the back cover may be a rectangular sheet. Two or more convex rectangular parts may be formed directly on the back cover. The convex rectangular parts, with respect to other portion of the back cover, protruding downwardly to press the optical guiding module. Such designs help increase robustness of the panel light apparatus.

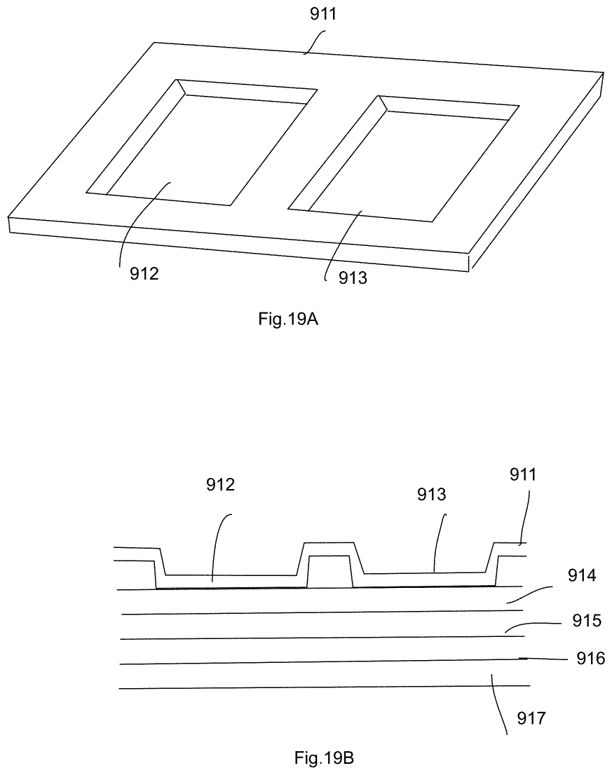

Please refer to FIG. 19A and FIG. 19B. FIG. 19A illustrates a back cover with convex portions and FIG. 19B illustrates how these convex portions press the optical guiding module.

In FIG. 19A, the back cover 911 has two convex portions 912, 913 facing downwardly to the optical guiding module.

In FIG. 19B, the two convex portions 912, 913 of the back cover 911 press an elastic layer 914. The elastic layer 914 presses the reflective layer 915, the light guiding layer 916, and the light diffusion layer 917.

In some embodiments, the light guiding layer and the light diffusion layer are fixed together at two opposite sides of the light guiding layer and the light diffusion layer. The first LED light bar is disposed facing another side instead of the two opposite sides of the light guiding layer and the light diffusion layer. In short, the fixed portion, which may be made of heating, pressing, ultrasound and causes certain shape changing at edge portion of the light guiding layer and the light diffusion layer, is kept away from the sides where LED modules emit light into. When two sides of the light guiding layer are disposed with LED modules, the other two sides may be used as the fixed part, applying glues, heat, ultrasound, and other sticking methods to fix the light guiding layer and the light diffusion layer together.

In some embodiments, a corner or more corners of the optical guiding module may have a positioning structure corresponding to the heat sink frame for ensuring the optical guiding module to be placed at a predetermined angle with respect to the heat sink frame. For example, during manufacturing, the optical guiding module may have specific sides for receiving light of LED modules. Besides, manufacturers or customers may place the optical guiding module top side down. With certain corners embedding with positioning structure, like a cut corner corresponding to a protruding block on the heat sink, the optical guiding module is ensured to be placed correctly as desired.

In some embodiments, the light guiding layer and the light diffusion layer are fixed with a clip. The clip comprising lens for guiding light of the first LED light bar into the light guiding layer. For example, the clips may contain a lens bar, corresponding to LED modules of the first LED light bar. The lens on the lens bar may enhance more light of the LED modules to correctly enter the light guiding layer in desired angles.

In some embodiments, the light diffusion layer are made of a deposition layer formed on the light guiding layer, and a surface of the deposition layer is processed for softening light.

In some embodiments, the light guiding layer and the light diffusion layer are two parts of the same PMMA substrate. The light escape points are formed inside the PMMA substrate. This design increases robustness of the panel light apparatus and decreases manufacturing cost.

In some embodiments, the light guiding layer and the light diffusion layer are two parts of the same PMMA substrate. The light escape points are formed inside the PMMA substrate. This design increases robustness of the panel light apparatus and decreases manufacturing cost.

Screws may also be used for fixing the light guiding layer and the light diffusion layer together as a single part. To prevent different size increasing during heating, the screws may be selected with elastic material. The diffusion layer may be a plastic think film to be fixed to the light guiding layer with static electricity. With the help of the static electricity, there may be tapes or protruding walls at peripheral edges of the light guiding layer for further fixing these layers together.

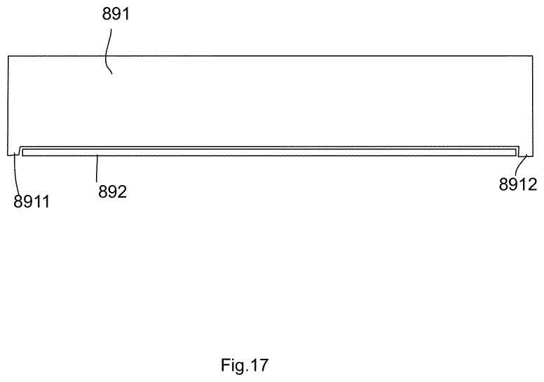

FIG. 17 illustrates a film type light diffusion layer 892. The light diffusion layer 892 is attached to the light guiding layer 891 with static electricity. There are blocking structures 8911, 8912 for keeping the light diffusion layer 891 in its desired position.

According to an embodiment, a panel light apparatus includes a heat sink frame, a first LED light bar, an optical guiding module, an elongated side cover and a back cover. The panel light apparatus may be installed below a ceiling, attach to a wall or installed in other applications. The heat sink frame defines light output shape, e.g. a rectangular light output shape. The thickness of the panel light apparatus is usually smaller than width of the light output shape. Usually, the thickness of the panel light apparatus is smaller than normal downlight devices so that the panel light apparatus does not need an additional installation cavity, e.g. in a ceiling.

The heat sink frame includes a plurality of frame bars forming a surrounding border. For example, if the heat sink frame has a rectangular shape, there are four frame bars at four sides. The four frame bars form a rectangular surrounding border. Please be noted that the frame bar may also be made of one or multiple frame bars to form different shapes, e.g. circular, ellipse, two connected rectangular shapes like a digit ‘8’ or other shapes.

The first LED light bar is disposed on an inner side of one of the frame bars for fixing the first LED light bar to the heat sink frame. Heat of the LED light bar is transmitted to the heat sink frame. The first LED light bar includes multiple first LED modules disposed along an elongated axis. A maximum spacing between adjust two first LED modules being a first width. For example, a rectangular panel light has four elongated frame bars. The first LED light bar has a similar shape as the frame bar to attach to. The first LED light bar has an elongated axis in parallel with the lateral side wall of the associated frame bar. For example, 101 LED modules are placed with 5 mm distance to each other within a length of a 50 cm LED light bar. The 5 mm distance is the first width. There may be some distance larger than others. In such case, the maximum value is taken as the first width.

Besides, the first LED light bar is a major heat source, and heat generated from the first LED light bar is transmitted to the frame bars of the heat sink frame.

The optical guiding module is placed in the surrounding border. For example, the surrounding border is a rectangular shape and the optical guiding module is also a similar rectangular shape but with a smaller size. The optical guiding module is placed in the enclosing border of the heat sink frame.

The optical guiding module may have a light diffusion layer and a light guiding layer. The light guiding layer may be a transparent plastic board a plurality of micro structures for guiding light received from a lateral side of the transparent plastic board to route in the light guiding layer and then escapes the light guiding layer from a plurality of micro optical structures, e.g. micro cavities, that may be formed on the transparent plastic board using laser beams or molding technologies.

The light guiding layer has a lateral side facing to LED modules of the first LED light bar for guiding light of the LED modules to the diffusion layer via the light guiding layer and then to escape from a front side of the optical guiding module.

The light diffusion layer is used for diffusing light so that the light would not look too hash for human eyes, e.g. to soften the output light and to avoid users see a series of strong light points.

In addition, the light guiding layer and the light diffusion layer are fixed together as an assembly module before being placed in the surrounding border. With such design, it is easy to assembly the final product by placing all components together. For example, when the light guiding layer and the light diffusion layer are fixed together as an assembly module, a manufacturer, even a distributor or a customer, may easily place these components together, instead of needing to positioning, aligning these components.

The elongated side cover is connected to the frame bar carrying the first LED light bar. The elongated side cover has a top surface facing to the light diffusion layer. A width of the elongated side cover is referred as the second width. The ratio between the first width to the second width is smaller than 1.5. That is, the result of taking the first width dividing with the second width is kept less than 1.5.

With such design, bright points problem may be solved or softened, making the overall light output more perfect.

The back cover is fixed to the heat sink frame for protecting the optical guiding module.

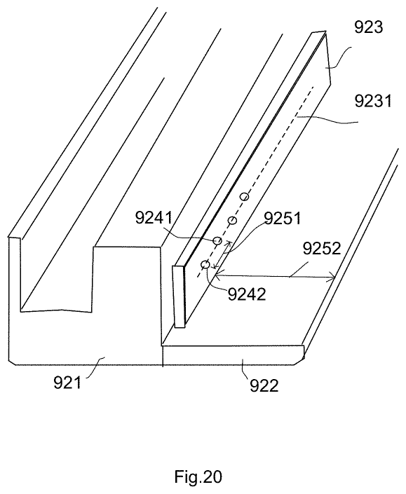

Please refer to FIG. 20. In FIG. 20, a frame bar 921 is disposed with a LED light bar 923. The LED light bar 923 is mounted with multiple LED modules 9241, 9242 disposed along an elongated axis 9231. The maximum distance between two adjacent LED modules is the first width 9251. There is an elongated side cover 922 connected to the frame bar 921. The width of the elongated side cover 922 is the second width 9252.

In the embodiment, the ratio between the first width 9251 and the second width 9252 is less than 1.5. For example, if the first width 9251 is 10 mm, the second width is larger than 15 mm.

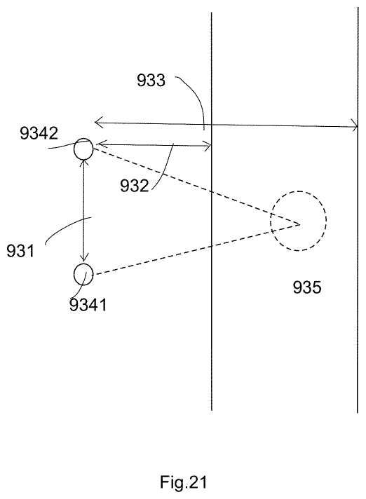

Please refer to FIG. 21. In FIG. 21, two LED modules 9341, 9342 are disposed with a distance of the first width 931. There is a bright point 935, which is undesired, causing imperfect output of the panel light. The bright point 935 is formed at a distance from the two LED modules. If the elongated cover has a smaller width 932, the bright point may be seen by users. If the elongated cover has a larger width 933, the bright point may be shielded, and not seen by users. Therefore, the ratio mentioned above solves the bright point problem.

In some embodiments, a reflective layer is disposed between the top surface of the elongated side cover and the light diffusion layer. Light emitting on the reflective layer above the elongated side cover is reflected back to the optical guiding module, and then after certain routing, the light finally moves out of the optical guiding module. This saves unnecessary light waste and prevent undesired heat generation.

In some embodiments, the reflective layer is a heat conductive layer for transmitting heat to the heat sink frame. In other words, the reflective layer, in addition to reduce light waste, the reflective layer above the elongated side cover may be made of metal or heat conductive plastic material for enhance overall heat dissipation of the panel light apparatus.

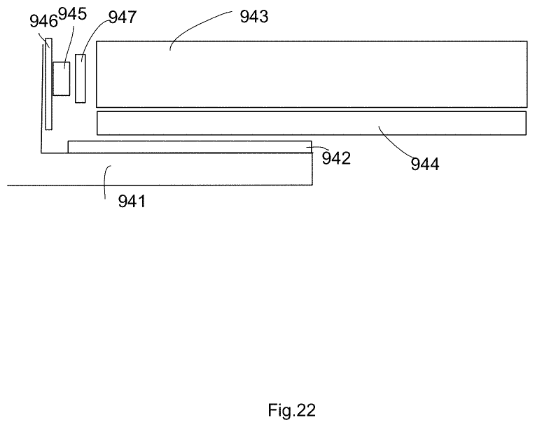

Please refer to FIG. 22. In FIG. 22, a LED module 945 emits light into a light guiding layer 943, then directing to a light diffusion layer 944. To solve the bright point problem, an elongated side cover 941 with proper width is disposed. In addition, a second diffusion layer 947 may be placed between the LED module 945 and the light guiding layer 943.

A reflective layer 946 may be disposed on the LED light bar that mounts the LED modules. Convex structures may be prepared on the reflective layer 946. In addition, a reflective layer 942 may also be disposed above the elongated side cover 941.

In some embodiments, there may also be second LED modules. A maximum spacing between adjust two second LED modules is a third width. The ratio between the third width to the second width is smaller than 1.5.

In some embodiments, the second LED modules and the first LED modules are arranged alternatingly to each other. Specifically, along the elongated axis as mentioned above, one first LED module is placed first, then one second LED module is placed, then another first LED module is placed, and then another second LED module is placed. With such order, the first LED modules and the second LED modules may be arranged alternating to each other.

In some other embodiments, the first LED modules and the second LED modules are arranged as two rows in parallel. In such embodiments, the first LED modules may form a line in parallel with the elongated axis as mentioned above. The second LED modules form another line also in parallel with the elongated axis as mentioned above. In such design, the two LED modules form two rows in parallel.

In some embodiments, the second LED modules are mounted on a second LED light bar on another frame bar opposite to the frame bar mounted with the first LED modules. Specifically, there are two LED light bars fixed on two opposite frame bars in a panel light apparatus. The first LED light bar is fixed with first LED modules and the second bar is fixed with second LED modules. The first LED modules and the second LED modules may have different color temperatures.

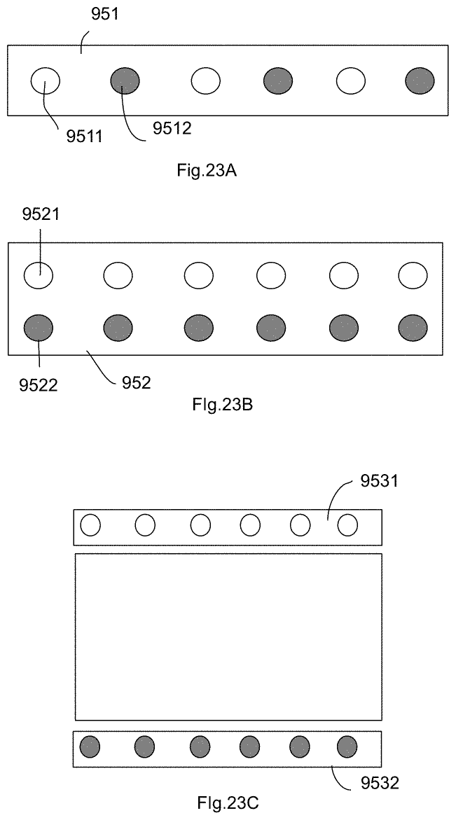

Please refer to FIG. 23A. FIG. 23A shows a first example of arranging two types of LED modules in a LED light bar. In FIG. 23A, a first LED module 9511 and a second LED module 9512 are arranged in alternating order to each other on the LED light bar 951, as illustrated in FIG. 23A.

Please refer to FIG. 23B. FIG. 23B shows a second example of arranging two types of LED modules in a LED light bar. In FIG. 23B, the first Led module 9521 and the second LED module 9522 are arranged in two parallel rows on a LED light bar 952.

Please refer to FIG. 23C. FIG. 23C shows using two LED light bars 9531, 9532 disposed on two opposite sides of a panel light apparatus.

In some embodiments, the first LED modules are connected in series and the second LED modules are connected in series. The first LED modules and the second LED modules have different color temperatures. The second LED modules are connected in series to a resistor before connecting to the first LED modules. With such configuration, when the total working current is increasing, the overall mixed color temperature may be adjusted in addition to its overall luminance level. With the resistor, the first LED modules and the second LED modules receive different current increasing speed and thus changes the mixed color temperature during changing its mixed brightness.

Such feature is capable of simulating day light from sunrise to full bright sunshine. This is an attractive feature, particularly for light devices that provide color temperature adjustment.

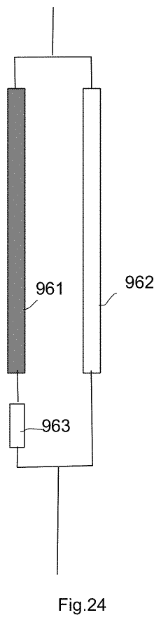

Please refer to FIG. 24. In FIG. 24, first LED light modules 961 are connected in series. Second LED modules 962 are also connected in series. The first LED modules 961 are connected in series to a resistor 963 and then connected to the second LED modules 962 in parallel.

In some embodiments, the elongated side cover has more apparent light diffusion effect than the light diffusion layer. Specifically, the elongated side cover may completely prevent any light to go through. In some other cases, the elongated side cover may be designed with light diffusion effect. Particularly, to prevent certain bright points to be seen, the elongated side cover may have stronger light diffusion effect than the light diffusion layer in the optical guiding module. In other words, bright points may be shielded or soften by the elongated side cover. More light is output while certain light effect is kept.

In some embodiments, the first LED light bar comprises multiple LED packages. Each LED package comprises LED modules of different color temperatures. For example, the first LED modules and the second LED modules are separately assembled together into multiple LED packages. In other words, each LED package may have one first LED module and one second LED module. To achieve different design needs, four lines, instead of two lines, may be provided for such LED modules. In such case, the color temperature may be adjusted while the LED packages may be placed close enough to prevent undesired light effect like bright points.

In some embodiments, a lens bar may be disposed facing to the first LED modules for diffusing light of the first LED modules before the light entering the light guiding layer. Specifically, such lens bar containing multiple lens corresponding to each LED module may be placed between the LED modules and the light guiding layer. With such design, light is diffused first and bright points may be eliminated or softened.

In some embodiments, a reflector layer may be disposed behind first LED modules. The reflective layer has concave texture for generating diffused reflecting light into the light guiding layer. Specifically, some light is emitted directly to the light guiding layer while some other light may be escape to the back side of the first LED modules, e.g. the surface of the first LED light bar. The reflective layer mentioned here may collect such light and reflect the light back into the light guiding layer. Furthermore, the reflective layer may be disposed with multiple concave structures, just like diffusion lens, for randomizing its reflected light. This may also help remove or soften the bright point problem.

In some embodiments, a diffusion layer between the first LED modules and the light guiding layer. In other words, light emitted to the light guiding layer is passing the second diffusing layer between the first LED modules and the light guiding layer. This may also help remove or soften the bright point problem.

In some embodiments, the first LED light bar is integrated with the elongated side cover as an assembling component. Since the parameter, like its width, of the elongated side cover is related to spacing between two adjacent LED modules on the LED light bar. It would be beneficial to integrate the LED light bar with the elongated side cover. In such design, manufactures may manufacture modules of LED light bars and elongated side covers with several different parameters and choose desired modules to be assembled in final product. In such design, the heat sink frame and other components may not need to be changed. Only the LED light bars and associated elongated side covers need to be selected or replaced.

In some embodiments, the first LED light bar has a plugging structure to be plugged into the frame bar of the heat sink frame. With such design, it would be much easier to assemble the first LED light bar to other components of the panel light apparatus. For example, no complicated welding is necessary when the plugging structure is strong enough to fix the first LED light bar to other components.

In some embodiments, the first LED light bar has a terminal to be plugged into the heat sink frame for receiving electricity. In addition to the plugging structures as mentioned above, the LED light bar may be disposed with a terminal so as to receive electricity and/or control signal from the heat sink frame.

Certain embedded connectors, e.g. metal strips or metal wires with corresponding insulation parts, may be disposed in the heat sink frame. Such embedded connectors may be even pluggable, e.g. no welding but only plugging in a corresponding plug-in structure.

In some embodiments, the elongated side cover is a plug-in component to be plugged to the heat sink frame. In some cases, the elongated side cover may be part of the frame bar. In some other cases, the elongated side cover may be an additional component to be plugged, or connected in other ways, to the heat frame sink.

In some embodiments, the panel light apparatus may include a driver box. The driver box has a slot for plugging an external plug-in module. There may be multiple types of the external plug-in modules to be plugged into the slot for extending the function of the driver box. In some application, an external plug-in module may provide color temperature adjustment of the panel light apparatus.

According to an embodiment, a panel light apparatus includes a heat sink frame, a first LED light bar, an optical guiding module, an elongated side cover and a back cover. The panel light apparatus may be installed below a ceiling, attach to a wall or installed in other applications. The heat sink frame defines light output shape, e.g. a rectangular light output shape. The thickness of the panel light apparatus is usually smaller than width of the light output shape. Usually, the thickness of the panel light apparatus is smaller than normal downlight devices so that the panel light apparatus does not need an additional installation cavity, e.g. in a ceiling.

The heat sink frame includes a plurality of frame bars forming a surrounding border. For example, if the heat sink frame has a rectangular shape, there are four frame bars at four sides. The four frame bars form a rectangular surrounding border. Please be noted that the frame bar may also be made of one or multiple frame bars to form different shapes, e.g. circular, ellipse or other shapes.

The first LED light bar is disposed on an inner side of one of the frame bars for fixing the first LED light bar to the heat sink frame. Heat of the LED light bar is transmitted to the heat sink frame. The first LED light bar includes multiple first LED modules disposed along an elongated axis. A maximum spacing between adjust two first LED modules being a first width. For example, a rectangular panel light has four elongated frame bars. The first LED light bar has a similar shape as the frame bar to attach to. The first LED light bar has an elongated axis in parallel with the lateral side wall of the associated frame bar.

Besides, the first LED light bar is a major heat source, and heat generated from the first LED light bar is transmitted to the frame bars of the heat sink frame.

The optical guiding module is placed in the surrounding border. For example, the surrounding border is a rectangular shape and the optical guiding module is also a similar rectangular shape but with a smaller size. The optical guiding module is placed in the enclosing border of the heat sink frame.

The optical guiding module may have a light diffusion layer and a light guiding layer. The light guiding layer may be a transparent plastic board a plurality of micro structures for guiding light received from a lateral side of the transparent plastic board to route in the light guiding layer and then escapes the light guiding layer from a plurality of micro optical structures, e.g. micro cavities, that may be formed on the transparent plastic board using laser beams or molding technologies.

The light guiding layer has a lateral side facing to LED modules of the first LED light bar for guiding light of the LED modules to the diffusion layer via the light guiding layer and then to escape from a front side of the optical guiding module.

The light diffusion layer is used for diffusing light so that the light would not look too hash for human eyes, e.g. to soften the output light and to avoid users see a series of strong light points.

In addition, the light guiding layer and the light diffusion layer are fixed together as an assembly module before being placed in the surrounding border. With such design, it is easy to assembly the final product by placing all components together. For example, when the light guiding layer and the light diffusion layer are fixed together as an assembly module, a manufacturer, even a distributor or a customer, may easily place these components together, instead of needing to positioning, aligning these components.

The back cover is fixed to the heat sink frame for protecting the optical guiding module.

In addition, a supplemental electronic device is attached to a bottom side of the heat sink frame. There are several useful supplemental electronic devices that may be attached to the bottom side of the heat sink frame. For example, an indicator for indicating an emergency working status, an indicator for indicating a wireless operation mode or connection status, a detector for detecting environment luminance level to determine whether to turn on, to turn off, or to adjust a luminance level of the panel light apparatus.

More details and examples are provided as follows for more clearly explaining these embodiments.

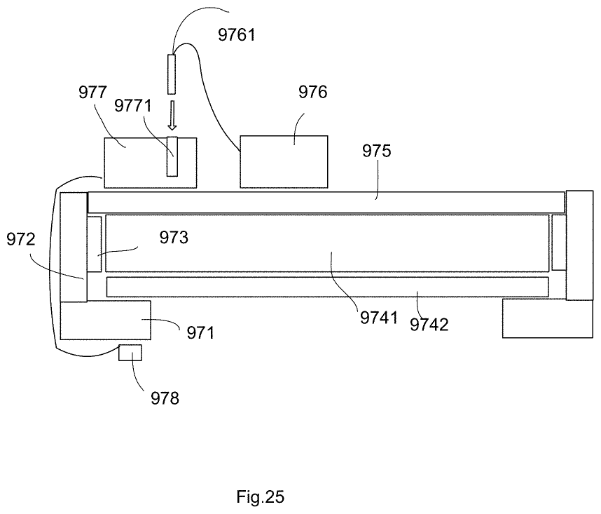

Please refer to FIG. 25. FIG. 25 illustrates a panel light apparatus with a supplemental electronic device.

In FIG. 25, the panel light apparatus embodiment has a LED light bar 973 mounted with LED modules. The LED modules emit light to the light guiding layer 9741. The light is routed for entering the light diffusion layer 9742 and then escape from the panel light apparatus.

There is a heat sink frame 972 with frame bars. The heat sink frame defines a surrounding border for storing the light guiding layer 9741 and the light diffusion layer 9742. The bottom surface 971 of the heat sink frame also helps holding the light diffusion layer 9742.

In addition, a supplemental electronic device 978 is attached to the bottom surface 971 of the heat sink frame 972. In this example, an external wire is used for connecting the supplemental electronic device 978 to a driver box 977. The driver box 977 mounted on a back cover 975 receives an external power source and converts the external power source to a driving current for the LED modules. In this example, there is also an emergency device 976 that contains an emergency battery and associated circuits. The emergency device 976 is connected to the driver box 977 by inserting a terminal 9761 into a slot 9771 of the driver box 977.

The status of the emergency device 976 is determined and shown via the supplemental electronic device 978, which may be a LED indicator, in this example.

In some embodiments, the supplemental electronic device is an indicator for showing an emergency device status. The supplemental electronic device is attached to the bottom surface of the heat sink frame with a tape. To prevent sudden electricity interrupt, people sometimes requires their light devices having the capacity of handling electricity interrupt, which is one of emergency situations. In such embodiments, an emergency battery is usually prepared. When an electricity interrupt occurs, a detector finds the situation and automatically routes power supply of the first LED modules from normal indoor power supply to the emergency battery.

However, it is important to notify users whether the emergency batter is still ok. Therefore, a low power is directed to an indicator, e.g. an LED indicator, to show the status of the emergency battery, which is part of an emergency device.

The indicator, in this case, is the supplemental electronic device. A tape may be used for attaching the indicator to the bottom surface of the panel light apparatus.

In some embodiments, the driver box has a slot for plugging in an emergency module for providing emergency power to the first LED modules when the external power source is interrupted. Specifically, the driver box may have a container for directly containing an emergency battery and corresponding circuit. Alternatively, the slot is for plugging a terminal of the emergency device, the terminal is further connected to the emergency battery.

In some embodiments, the bottom surface has a plug-in socket for plugging in an indicator as the supplemental electronic device. In such embodiments, the indicator or other supplemental electronic device is not directly fixed to the bottom surface of the heat sink frame. Instead, a plug-in socket may be provided. There may be different types of supplemental electronic devices to be integrated with the same panel light apparatus, depending on customer needs. In some case, the plug-in socket may even be kept empty without plugging any device, if needed.

The plug-in socket is further connected to the first LED modules or other components of the panel light apparatus, e.g. an emergency battery control circuit via certain embedded connectors pre-installed inside the heat sink frame.

Such embedded connectors may be wires, conductive clips or other electricity connectors. The embedded connectors may be even designed as a plugging style. Specifically, no welding is needed for assembling the embedded connectors to the heat sink frame. Furthermore, it is convenient for users to adjust or replace a different kind of embedded connector to the same panel light apparatus depending on different needs or product requirements, e.g. different pricing.

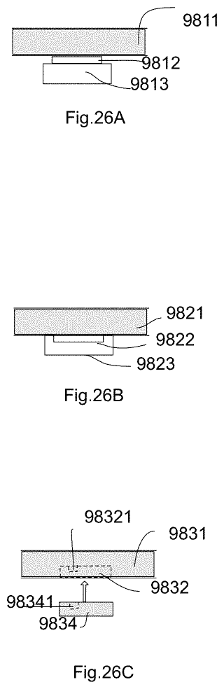

Please refer to FIG. 26A, FIG. 26B and FIG. 26C. The three drawings show three exemplary ways for attaching the supplemental electronic device to the heat sink frame.

In FIG. 26A, the supplemental electronic device 9813 is attached to a bottom surface 9811 of the heat sink frame with a tape 9812.

In FIG. 26B, the supplemental electronic device 9823 has a magnet unit 9822 to attach to a metal material bottom surface 9821 of the heat sink frame.

In FIG. 26C, the bottom surface o9631 of the heat sink frame 9831 is embedded with a socket 9832. The supplemental electronic device 9834 is inserted into the socket 9832. In addition, the socket 9832 may have a pin 98321 corresponding to a pin socket 98341 of the supplemental electronic device 9834 as structural and electrical connection to the driver box.

As mentioned above, there may be various kinds of supplemental electronic device. For example, the supplemental electronic device may be an indicator for showing a status of an emergency device. For another example, the supplemental electronic device may be a light detector for detecting an environment luminance level, the driver box determines turning on the first LED modules automatically according to the detected environment luminance level. For example, when there is a window in a room and sunshine comes into the room in day time. The luminance level is sufficient and detected. The first LED modules may be turn on with a lower luminance level. Alternatively, the first LED modules may also have only turn-on and turn-off modes, depending on product requirements.

In some other embodiments, the supplemental electronic device may be a motion sensor for detecting whether there is a person moving around the panel light apparatus. For example, even in night time when the panel light apparatus is turned off, the panel light apparatus may be turned on automatically when detecting some person moving around the panel light apparatus. The bottom surface of the heat sink frame is a great place for placing such sensors or detectors. Such detectors may contain an IR (Infrared) sensor, or a radar sensor with associated circuits. Part of the components may be placed in the driver box. The wiring for transmitting electricity and signals may be routed via the heat sink frame.

In some embodiments, one supplemental electronic device of one panel light apparatus may be shared by multiple panel light apparatuses. In other words, when multiple panel light apparatuses are installed as a cluster, e.g. at the same room, only one or some panel light apparatuses need to be added such supplemental electronic devices. Alternatively, every panel light apparatus is disposed its own supplemental electronic device, like indicators, light sensors, motion sensors, but information of these supplemental electronic devices are shared among these panel light apparatuses.

The information may be shared via a wire or a wireless channel. For example, when a cluster of panel light apparatuses are installed to a ceiling, users may use wires to plug in pre-installed socket to connect these panel light apparatuses together as a cluster. When these panel light apparatuses are connected, information or control commands may be received or sent to the supplemental electronic device.

With such design, manufacturing cost may be reduced when some panel light apparatuses may share the supplemental electronic device of other panel light apparatus, instead of installing one such supplemental electronic device on the panel light apparatus. Alternatively, even every panel light apparatus is disposed one supplemental electronic device, collected information or control commands of the supplemental electronic devices may be shared among these panel light apparatuses.

For example, a day light sensor of a panel light apparatus that is installed close to a window may be designated as the major reference for determining whether a cluster of panel light apparatuses need to be turned on or to turn off. This saves more accuracy and sometimes decreases control complexity.

In some embodiments, multiple panel apparatuses may share the same set of control circuits in a driver box of one panel light apparatus. In such design, multiple panel light apparatuses may be controlled together with one shared control circuit. This may save manufacturing cost and/or decrease control complexity.

In some embodiments, multiple panel apparatuses may even share the same driver box. In such design, even driving current is supplied from a driver box to multiple panel light apparatuses. This is particularly helpful when in most office or home, multiple panel light apparatuses are installed close to each other to provide sufficient luminance level or to cover more areas. When a driver box may be shared among multiple panel light apparatuses, the installation is simplified and the cost of the product is also reduced.

In some embodiments, multiple panel light apparatuses may be connected in series, in addition to sharing one driver box for these panel light apparatuses.

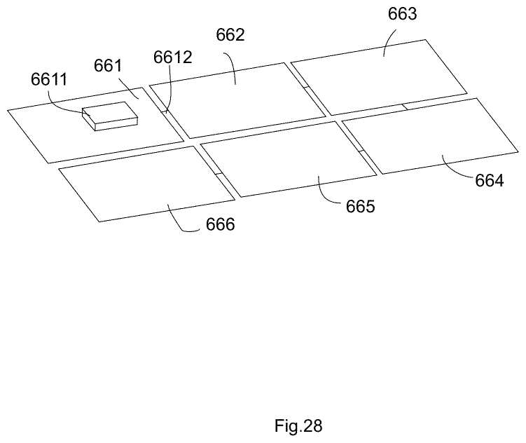

Please refer to FIG. 28. FIG. 28 illustrates multiple panel light apparatuses as a cluster for sharing components.

As mentioned above, multiple panel light apparatuses 661, 662, 663, 664, 665 and 666 are connected, e.g. via a predetermined socket 6612 and corresponding plugging structures. As mentioned above, the driver box 6611 may be shared among multiple panel light apparatuses 661, 662, 663, 664, 665 and 666.

In addition, supplemental electronic devices may be shared, or even the electricity and control signals.

According to an embodiment, a panel light apparatus includes a heat sink frame, a first LED light bar, an optical guiding module, an elongated side cover, a back cover and a driver box. The panel light apparatus may be installed below a ceiling, attach to a wall or installed in other applications. The heat sink frame defines light output shape, e.g. a rectangular light output shape. The thickness of the panel light apparatus is usually smaller than width of the light output shape. Usually, the thickness of the panel light apparatus is smaller than normal downlight devices so that the panel light apparatus does not need an additional installation cavity, e.g. in a ceiling.

The heat sink frame includes a plurality of frame bars forming a surrounding border. For example, if the heat sink frame has a rectangular shape, there are four frame bars at four sides. The four frame bars form a rectangular surrounding border. Please be noted that the frame bar may also be made of one or multiple frame bars to form different shapes, e.g. circular, ellipse or other shapes.

The first LED light bar is disposed on an inner side of one of the frame bars for fixing the first LED light bar to the heat sink frame. Heat of the LED light bar is transmitted to the heat sink frame. The first LED light bar includes multiple first LED modules disposed along an elongated axis. A maximum spacing between adjust two first LED modules being a first width. For example, a rectangular panel light has four elongated frame bars. The first LED light bar has a similar shape as the frame bar to attach to. The first LED light bar has an elongated axis in parallel with the lateral side wall of the associated frame bar.

Besides, the first LED light bar is a major heat source, and heat generated from the first LED light bar is transmitted to the frame bars of the heat sink frame.

The optical guiding module is placed in the surrounding border. For example, the surrounding border is a rectangular shape and the optical guiding module is also a similar rectangular shape but with a smaller size. The optical guiding module is placed in the enclosing border of the heat sink frame.

The optical guiding module may have a light diffusion layer and a light guiding layer. The light guiding layer may be a transparent plastic board a plurality of micro structures for guiding light received from a lateral side of the transparent plastic board to route in the light guiding layer and then escapes the light guiding layer from a plurality of micro optical structures, e.g. micro cavities, that may be formed on the transparent plastic board using laser beams or molding technologies.

The light guiding layer has a lateral side facing to LED modules of the first LED light bar for guiding light of the LED modules to the diffusion layer via the light guiding layer and then to escape from a front side of the optical guiding module.

In addition, the light guiding layer and the light diffusion layer are fixed together as an assembly module before being placed in the surrounding border. With such design, it is easy to assembly the final product by placing all components together. For example, when the light guiding layer and the light diffusion layer are fixed together as an assembly module, a manufacturer, even a distributor or a customer, may easily place these components together, instead of needing to positioning, aligning these components.

The back cover is fixed to the heat sink frame for protecting the optical guiding module. The driver box converts an external power to a driving current for the first LED modules.

In addition, the panel light apparatus also has a multi-type connector structure for selectively connecting to one of multiple types of fixing devices. The fixing devices are corresponding to different types of stations for fixing the panel light apparatus to one selected station.

Specifically, for different types of stations that provide different connection methods, different fixing devices need to be used. With the multi-type connector structure, users or manufacturers first determine what type of station they need to face, and choose accordingly a corresponding fixing device to connect on the multi-type connector structure. When the chosen fixing device is installed to the multi-type connector structure, the panel light apparatus may be properly fixed to the station as needed.

Such configuration makes it more convenient and more flexible to prepare components and save storage cost.

In some embodiments, the multi-type connector structure includes multiple screw holes. A portion of these screw holes are shared by different fixing devices.

For example, in some embodiments, the panel light apparatus is directory fixed to a station, e.g. a ceiling structure, by fastening screws into corresponding screw holes.

In some other embodiments, a portion of the screw holes are used for connecting to spring clips. Such spring clip has a first part with a first end connected to the screw holes and with a second end connected to a second part with a spring. The second part is elastically expandable with respect to the first part for inserting into a cavity of one of the stations and then expanded to fix to a station.

Specifically, the overall size of the first part and the second part of the spring clip may be squeezed to decrease to enter an entrance of an installation hole. After the spring clip enters the entrance hole, the second part recovers its respective distance to the first part of the spring clip, i.e. to expand, and thus to prevent the panel light apparatus to escape from the entrance hole.

In some examples, such spring clips may be installed on two opposite sides of the heat sink frame. More than two spring clips may also be used for larger panel light apparatus.

In some embodiments, a portion of screw holes are used for connecting to vertical bars. The vertical bars have protruding parts in lateral sides of the vertical bars. Such fixing devices are used for stations that have one or more elastic clip receivers. The elastic clip receiver has a concave space for containing the protruding part of the vertical bar for fixing the panel light apparatus to said one station.

Specifically, the elastic clip of such station has an entrance slit for receiving the vertical bar. When the protruding part enters the concave space of the elastic clip, the elastic force keeps the protruding part of the vertical bar in the concave space and thus fixes the panel light apparatus to the station.

Some screw holes on the panel light apparatuses may be shared by multiple fixing devices. For example, the vertical bar and the spring clip may share one screw hole while using additional different screws.

In some embodiments, the fixing device is fixed to the multi-type connector structure with a one-way connection unit. For example, the one-way connection unit may have an inverse hook so that it is easier to attach the fixing device to the multi-type connector structure than detach the fixing device away from the multi-type connector structure.

In other words, in addition to using screw holes, other devices may be used for installing the fixing devices.

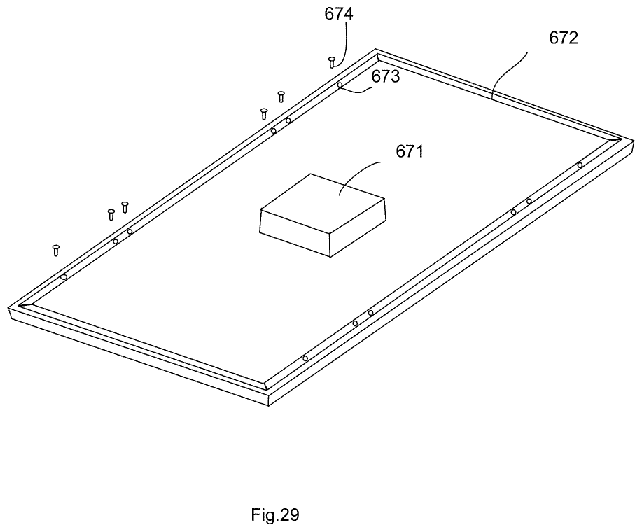

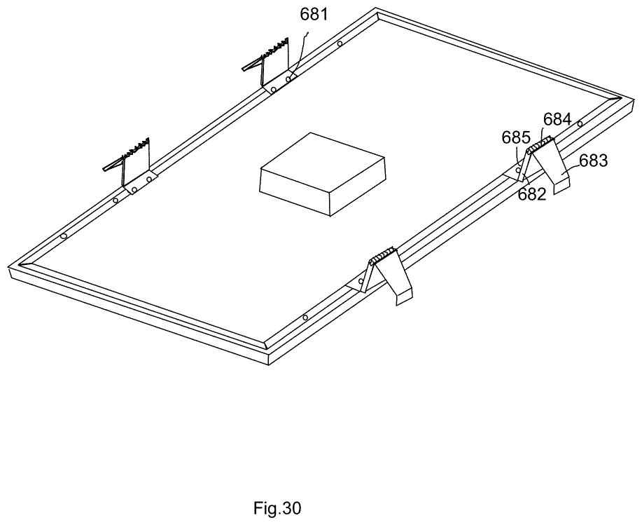

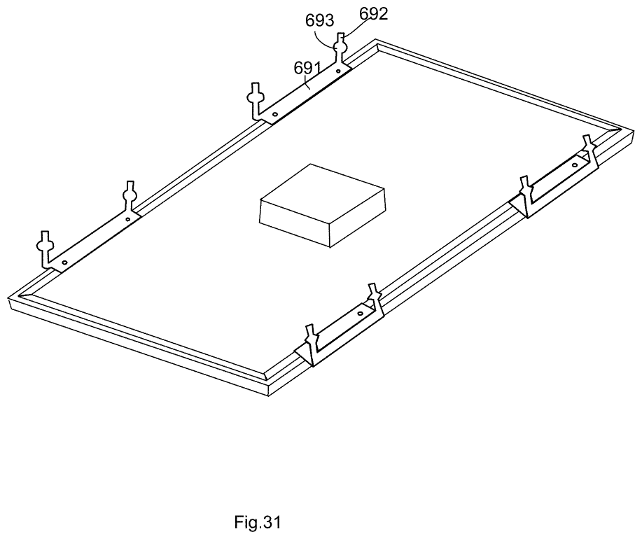

Please refer to FIG. 29, FIG. 30 and FIG. 31. The three drawings illustrate a panel light apparatus embodiment that has a multi-type connector structure for three different fixing devices for being fixed to a station, like a structure, a cavity or a pre-installed structure on a ceiling.

In FIG. 29, there are multi-type connector structures 673, screw holes in this example, on the heat sink frame 672. In FIG. 29, the fixing devices 674 are screws. In such application, screws are fixed to the screw holes and the panel light apparatus is directly fixed to a ceiling.

In FIG. 30, some screw holes 681 are also used for the second type of fixing device 685. In this example, the fixing device 685 is a spring clip. The spring clip has a first part 682 connected to a second part 683 via a spring 684 so that the second part 683 may be moved with respect to the first part 682 to shrink overall size to enter an entrance hole. After the panel light is placed into the entrance hole, the second part 683 is recovered to its original place and makes the spring clip staying in the installation cavity.

In FIG. 31, the fixing device 691 has a vertical bar 692. The vertical bar 692 further has a protruding part 693. The protruding part 693 may be used for keeping the fixing device 691 staying in a corresponding space so as to fix the panel light apparatus in a station.

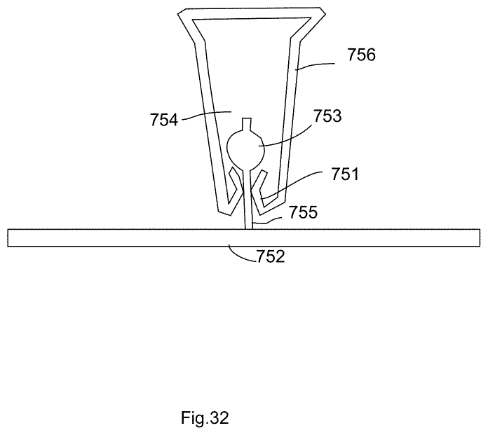

Please refer to FIG. 32. FIG. 32 illustrates how an elastic clip receiver 756 of a station to lock a vertical bar 755 as mentioned in FIG. 31.

In FIG. 32, the protruding part 753 keeps the fixing device to stay in the concave space 754 after the vertical bar 755 enters the elastic entrance 751 of the elastic clip receiver 756. Since the vertical bar 755 is fixed to the heat sink frame 752, the panel light apparatus is fixed to the station with the elastic clip receiver 756.

In some embodiment, the fixing device has an embedded connector for routing electricity to the first LED modules. In some embodiments, the heat sink may have embedded connectors, e.g. hidden and plugged in the frame bar of the heat sink frame. In such case, the fixing devices may also fix to the heat sink frame and may be embedded with wires or other connectors for transmitting electricity or control signals from or to the driver box or other devices.

In some embodiments, the driver box is fixed to the back cover and placed away from peripheral part of the back cover. For example, the driver box is fixed at middle of the back cover.

In some embodiments, the multi-type connector structure is placed on a different frame bar other than the frame bar disposing the first LED light bar. For example, there are LED light bars installed on two opposite sides of a panel light apparatus. The other two unused sides of the heat sink frame may be used for disposing the multi-type connector structures, so as to perform wire connection or prevent damage of components.

In some other embodiments, the multi-type connector structure is placed on the same frame bar disposing the first LED light bar. With such design, the multi-type connector device, which further connected to a fixing device, may help perform heat dissipation, particularly heat generated from the LED light bar.

In some embodiments, the multi-type connector structure and the fixing device is also attracted by magnetic force. By using magnetic components, it is easier to assemble the multi-type connector structure to corresponding fixing devices. This is particularly helpful when the design is to be used by distribution sellers that assemble the panel light apparatuses.

In some embodiments, the multi-type connector structure is fixed on a fixing bar. The fixing bar is used for fixing the back cover and the first LED light bar to the heat sink frame. Specifically, the multi-type connector structure is fixed indirectly to the heat sink frame, via an intermediate unit, the fixing bar. In following drawings and examples, fixing bars may be used for fixing the LED light bar and the optical guiding module to the heat sink frame. In this embodiment, the multi-type connector structure is fixed on the fixing bar first. Such design makes post-assembling easier, particularly when there is more than one fixing device to be installed on one side of the heat sink frame.

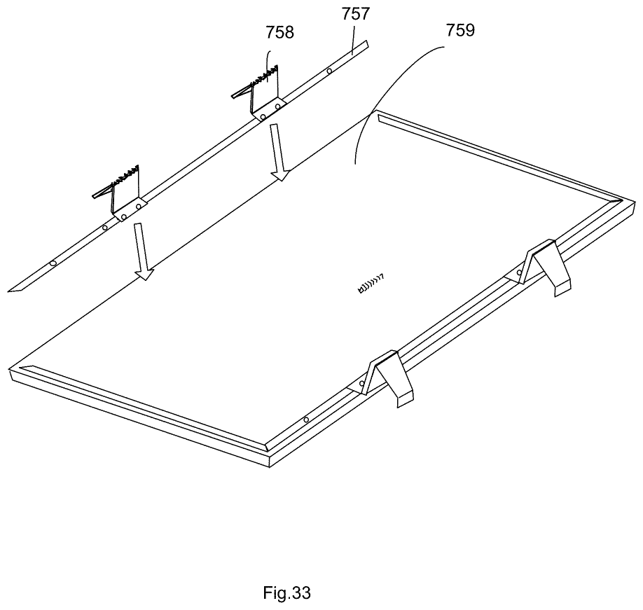

Please refer to FIG. 33. FIG. 33 illustrates that the fixing device 758 is firstly fixed to a fixing bar 757. The fixing bar 757 is further fixed to the heat sink frame 759.

In other embodiments, the multi-type connector structure is fixing to a sliding bar to be inserted into a corresponding track of the heat sink frame. In other words, the sliding bar replaces the fixing bar explained in previous paragraph. A corresponding track of the heat sink frame may be designed so that the sliding bar with fixing devices may be directly to the heat sink frame.

In some embodiments, the multi-type connector structure is fixed to a fixing frame, and the fixing frame is fixed to the heat sink frame. In such design, particularly when there are multiple multi-type connector structures. These multi-type connector structures, sometimes further including fixing devices thereon, are fixed to the fixing frame. Then, the fixing frame is attached to the heat sink frame, e.g. by clipping or screws.

In some embodiments, the driver has a slot for connecting to an external emergency battery. For example, the driver box may have a USB socket to connect to a common USB battery box. Furthermore, the multi-type connector structure may also be able to connect to a temporary stand so as to keep the panel light apparatus at a predetermined pose when necessary. For example, when the USB battery box is plugged, the panel light apparatus may be removed from the ceiling and placed on a table. At such time, the temporary stand and the USB battery box makes the panel light apparatus a temporary light apparatus for emergency use.

In some embodiments, the multi-type connector structure is used for fix to another panel light apparatus as a module. For example, multiple panel light apparatuses may be combined as a cluster. The multi-type connector structures may be used for fixing to other panel light apparatuses. Furthermore, the multi-type connector structures may also help for transmitting electricity and even control signals.

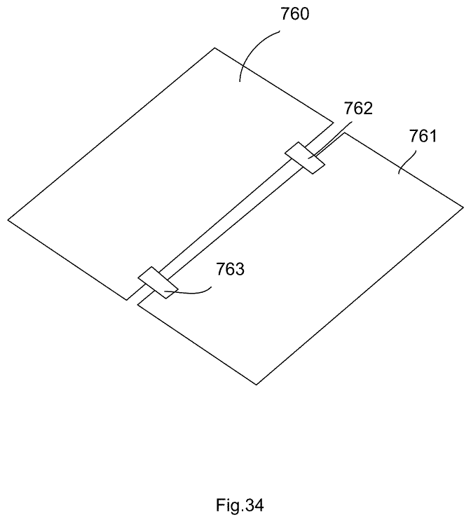

Please refer to FIG. 34. FIG. 34 illustrates that two panel light apparatuses 760, 761 are combined with fixing device 762, 763. In this example, it is shown that the multi-type connector structure, in addition to fix the panel light apparatus to a station, may also be used for fixing multiple panel light apparatuses together.

In some embodiments, the driver box controls the first LED modules to provide an operation status of an emergence device. Instead of using a specific indicator for showing whether an emergency battery and associated circuits are normal, certain testing procedure and light patterns may be provided to tell users whether the emergency battery and associated circuits are working normally. For example, every time when the panel light apparatus is turned on, the first LED modules are turned on and turned off for three times in three seconds, if the emergency battery is ok. A blinking light pattern may be used for indicating users that there is certain problem in the emergency battery.

In some embodiments, the driver box may be disposed with a driver circuit. The driver circuit may detect dynamically the status of the emergency battery. Most batteries may have a shorter life span if they are not used, not charged, or not discharged for a long time. The driver circuit may be coded to execute a charging, discharging schedule for increasing the life span of the emergency battery.

In some embodiments, the supplemental electronic device disposed on the bottom side of the heat sink frame may be used for connecting to an external battery device, like common USB battery boxes people usually carry for charging their mobile phones. In such case, the supplemental electronic device may be an USB socket for connecting to a USB battery box as emergency use.

In earthquakes, typhoon, or hospital situations, such function may be particularly important and helpful. Since many people today carry USB battery boxes with them, it is not difficult to use such USB battery box as an emergency purpose, particularly when the pre-installed emergency battery in the panel light apparatus is running out of electricity or out of order.

In some embodiments, there may be a holding structure, like a hook, a containing box, a clip or other structures for holding the USB battery box mentioned above. For example, when there is a sudden electricity interrupt, users may just connect their portable USB battery box to the panel light. It is quite different to provide light from a ceiling and from a table when accident happens. When one USB battery box is running out of electricity, another USB battery box may be replaced immediately, which sometimes may even save human life.

In some embodiments, the heat sink frame may further have a temporary stand so that the panel light apparatus is located at a predetermined position to work normally. In certain extreme cases, the panel light apparatuses may even be used as a temporary light source. If there is a revocable stand that helps the panel light apparatus to stand as a pose for emitting light to a desired direction, this makes the panel light apparatus even more helpful.

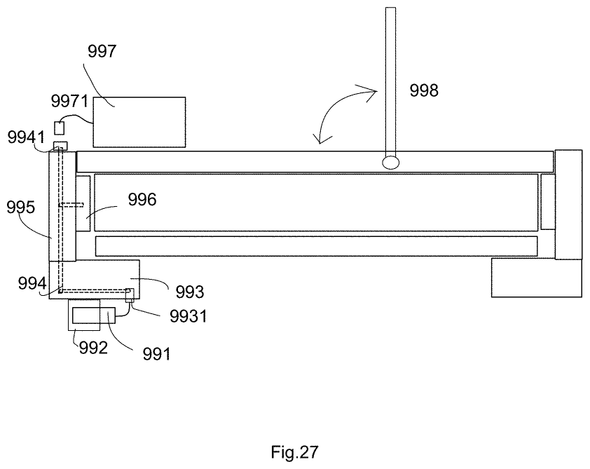

Please refer to FIG. 27, which illustrates another panel light apparatus embodiment. In FIG. 27, the panel light apparatus has a temporary stand 998 that may be used when the panel light apparatus is not installed to a ceiling but instead being placed on a table or on the ground.

In FIG. 27, it also shown embedded connectors 984 in the heat sink frame 995. The embedded connector 984 may be used for connecting the LED module 996 and the supplemental electronic device 9931. In this example, the supplemental electronic device 9931 is a USB socket. A common USB battery box 991 may be inserted to the supplemental electronic device 9931. A holder 992 may be provided to hold the USB battery box temporarily. The electricity of the USB battery box is routed via the supplemental electronic device 9931, the embedded connectors 994 to a socket 9941. The driver box 997 has a corresponding terminal 9971 to be plugged into the socket 9941.

When there is a sudden electricity interrupt, electricity of the USB battery box 991 is routed to the LED modules 996 via the controlling of the driver box 997.

In some embodiments, the driver box switches from a normal mode to an emergency working mode when an emergency battery is started to supply electricity to the first LED modules. The current supplied to the first LED modules is different between the emergency mode and the normal mode. For example, in emergency working mode, the luminance level of the first LED modules may be adjusted to a lower level.

In some embodiments, particularly when the driver box has a wireless circuit for receiving more complicated commands, an estimated time period for electricity interrupt may be provided to the driver box. The driver box calculates current battery volume and related history statistics and designs an electricity scheme, trying to keep the panel light apparatus to keep providing light during the estimated time period.

In some embodiments, a wire has a first end connecting to the driver box and has a second end connecting to an indicator, the indicator is attached to the bottom surface of the heat sink frame with a tape.

In some other embodiments, a wire has a first end connecting to the driver box and has a second end connecting to an indicator, the indicator is attached to the bottom surface of the heat sink frame with a magnet unit.

According to an embodiment, a panel light apparatus includes a heat sink frame, a first LED light bar, an optical guiding module and a back cover.

The heat sink frame includes multiple frame bars forming a surrounding border. The first LED light bar is fixed to an inner side of one of the frame bars for fixing the first LED light bar to the heat sink frame. Heat of the LED light bar being transmitted to the heat sink frame.

In some embodiments, the optical guiding module includes a light guiding layer and a light diffusion layer. The LED modules of the first LED light bar emits light into the light guiding layer and then the light is directed to the light diffusion layer to escape.

In some other embodiments, the optical guiding module may further include a reflective layer above the light guiding layer so as to reflect lights escape from the undesired directions back into the light guiding layer and finally to emit into the light diffusion layer.

In some other embodiments, there is further an elastic layer between the back cover and the reflective layer so as to transmit pressure from the back cover to ensure there is no spacing between the reflective layer and the light guiding layer, and no spacing between the light guiding layer and the light diffusion layer. This reduces unnecessary light lost and increase overall luminance efficacy.

The back cover is fixed to the heat sink frame for protecting the optical guiding module.

In some embodiments, the light diffusion layer and the light guiding layer are fixed with a first glue hardened by applying an ultra-violet light.

In some embodiments, furthermore, the reflective layer and the light guiding layer are fixed with a second glue hardened by applying the ultra-violet light. Specifically, three layers of the optical guiding modules are fixed together with glues. The glues are hardened with ultra-violet light and can be applied to the two glues directly or in sequence.

In some embodiments, the second glue between the reflective layer and the light guiding layer may include heat conductive material like metal powder, for enhancing heat dissipation.

In some embodiments, the first glue may contain plastic transparent balls with a diameter less than 0.4 mm. Such plastic transparent balls may further help diffusing light so as to make the light diffusion layer thinner.

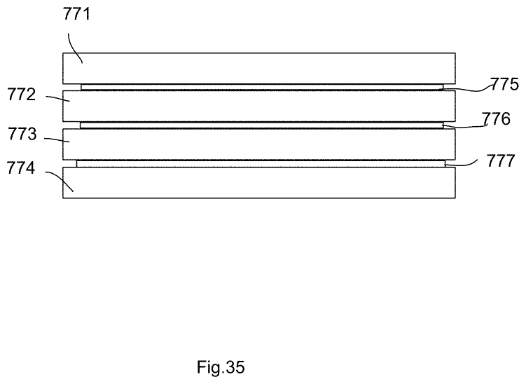

Please refer to FIG. 35. FIG. 35 illustrates an example of a light guiding module.

In FIG. 35, an elastic layer 771 is fixed to a reflective layer 772 with a third glue 775. The reflective layer 772 is fixed to a light guiding layer 773 with a second glue 776. The light guiding layer 773 is fixed to the light diffusion layer 774 with a third glue 777.

Such glue may be transparent and thus does not affect light emission too much.

In some embodiments, the back cover has a first clip clipping a first side of the reflective layer, the light guiding layer and the light diffusion layer and has a second clip clipping a second side of the reflective layer. The light guiding layer and the light diffusion layer, and the first side is opposite to the second side.

Specifically, two clips are clipping two opposite sides of the multiple layers of the optical guiding module, while leaving other two sides for light to emit into the light guiding layer.

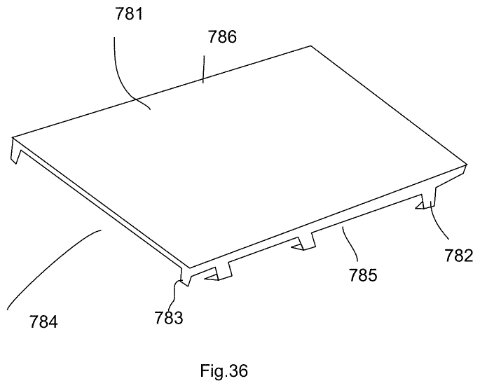

Please refer to FIG. 36. FIG. 36 illustrates an embodiment of a back cover.

In FIG. 36, a back cover 781 has multiple clips 782 for clipping layers of the optical guiding module on a first side 785 and a second side 786. Furthermore, the back cover 781 has a stopper structure 783 at a corner of the third side 784 to prevent any layer of the optical guiding module to escape.

To prevent any layer to escape from the optical guiding module by accident, a stopper structure may be disposed at the third side at a corner of the back cover for preventing the reflective layer, the light guiding layer or the light diffusion layer to escape from the third side.

In some embodiments, the back cover has a convex portion pressing the reflective layer to keep the reflective layer leaving no space with the light guiding layer. This design may save the need of inserting an elastic layer.

Otherwise, in some embodiments, there may be an elastic layer on the reflective layer. In addition, a third glue may be applied between the elastic layer and the reflective layer.

Similarly, the third glue is hardened together with the first glue and the second glue in the same procedure.

In addition, the third glue has heat dissipation characteristics, e.g. containing metal powder, so that heat may be transmitted to the back cover to increase life span of the components of the panel light apparatus.

In addition to the above-described embodiments, various modifications may be made, and as long as it is within the spirit of the same invention, the various designs that can be made by those skilled in the art are belong to the scope of the present invention.

1. A panel light apparatus, comprising:
a heat sink frame, comprising a plurality of frame bars forming a surrounding border;
a first LED light bar fixed to an inner side of one of the frame bars for fixing the first LED light bar to the heat sink frame, heat of the LED light bar being transmitted to the heat sink frame;
an optical guiding module to be placed in the surrounding border, the optical guiding module comprising a light diffusion layer, a light guiding layer and a reflective layer, a lateral side of the light guiding layer facing to LED modules of the first LED light bar for guiding light of the LED modules to the diffusion layer via the light guiding layer and then to escape from a front side of the optical guiding module, the light guiding layer, the light diffusion layer and the reflective layer being fixed together as a single part, the light guiding layer, the light diffusion layer and the reflective layer being kept together without falling apart even before the single part being placed in the surrounding border, there being no spacing between the reflective layer and the light guiding layer; and
a back cover fixed to the heat sink frame for protecting the optical guiding module.

2. The panel light apparatus of claim 1, wherein the light diffusion layer and the light guiding layer are fixed with a first glue hardened by applying an ultra-violet light.

3. The panel light apparatus of claim 2, wherein the reflective layer and the light guiding layer are fixed with a second glue hardened by applying the ultra-violet light.

4. The panel light apparatus of claim 3, wherein the second glue comprises heat conductive material.

5. The panel light apparatus of claim 3, wherein the first glue and the second glue are hardened by the same procedure using the same ultra-violet light.

6. The panel light apparatus of claim 1, wherein the first glue comprises plastic transparent balls with a diameter less than 0.4 mm.

7. The panel light apparatus of claim 1, wherein the back cover has a first clip clipping a first side of the reflective layer, the light guiding layer and the light diffusion layer and has a second clip clipping a second side of the reflective layer, the light guiding layer and the light diffusion layer, and the first side is opposite to the second side.

8. The panel light apparatus of claim 7, wherein the LED modules emits light from a third side of the light guiding layer, instead of the first side or the second side.

9. The panel light apparatus of claim 7, wherein there is a stopper structure at the third side at a corner of the back cover for preventing the reflective layer, the light guiding layer or the light diffusion layer to escape from the third side.

10. The panel light apparatus of claim 8, wherein the back cover has a convex portion pressing the reflective layer to keep the reflective layer leaving no space with the light guiding layer.

11. The panel light apparatus of claim 4, further comprising an elastic layer on the reflective layer.

12. The panel light apparatus of claim 11, wherein a third glue is applied between the elastic layer and the reflective layer.

13. The panel light apparatus of claim 12, wherein the third glue is hardened together with the first glue and the second glue in the same procedure.

14. The panel light apparatus of claim 12, wherein the glue has light reflective characteristics.

15. The panel light apparatus of claim 1, wherein the light guiding layer and the light diffusion layer are fixed together at two opposite sides of the light guiding layer and the light diffusion layer, the first LED light bar is disposed facing another side instead of the two opposite sides of the light guiding layer and the light diffusion layer.

16. The panel light apparatus of claim 1, wherein a corner of the optical guiding module has a positioning structure corresponding to the heat sink frame for ensuring the optical guiding module to be placed at a predetermined angle with respect to the heat sink frame.

17. The panel light apparatus of claim 1, wherein the light guiding layer and the light diffusion layer are fixed with a clip, the clip comprising lens for guiding light of the first LED light bar into the light guiding layer.

18. The panel light apparatus of claim 1, wherein the light diffusion layer are made of a deposition layer formed on the light guiding layer, and a surface of the deposition layer is processed for softening light.

19. The panel light apparatus of claim 1, wherein the light guiding layer and the light diffusion layer are two parts of the same PMMA substrate, the light escape points are formed inside the PMMA substrate.

20. The panel light apparatus of claim 1, wherein the light guiding layer and the light diffusion layer are made of the same plastic material.
